(19) United States
(12) Patent Application Publication
(10) Pub. No.: US 2026/0082999 A1
(43) Pub. Date: Mar. 19, 2026

(54) SEMICONDUCTOR DEVICE AND METHOD FOR MANUFACTURING THE SAME

(71) Applicant: Intel Corporation, Santa Clara, CA (US)

(72) Inventors: Po-Yao LIN, New Taipei City (TW); Kai Chiang WU, Hsinchu City (TW); Jong Sik PAEK, Zhubei City (TW); Derchang KAU, Cupertino, CA (US)

(21) Appl. No.: 19/002,888

(22) Filed: Dec. 27, 2024

Related U.S. Application Data
(63) Continuation-in-part of application No. 18/884,172, filed on Sep. 13, 2024.

(51) Int. Cl. H01L 25/065; H01L 21/48; H01L 21/56; H01L 23/00; H01L 23/15; H01L 23/31; H01L 23/498; H10B 80/00; H10D 89/10

(52) U.S. Cl. CPC H10W 90/00; H10W 70/093; H10W 70/65; H10W 70/692; H10W 74/016; H10W 90/401; H10B 80/00; H10D 89/10; H10W 72/07552; H10W 72/07553; H10W 72/527; H10W 72/531; H10W 72/5445; H10W 72/823; H10W 72/884; H10W 74/10; H10W 74/117; H10W 90/24; H10W 90/732; H10W 90/754

(57) ABSTRACT

The disclosure describes a semiconductor device and a method for fabricating a semiconductor device. The semiconductor device includes: a first module and a second module stacked vertically on the first module, each module includes multiple dies stacked vertically within an insulation layer, wherein each die higher than a lower die is laterally offset from the lower die forming a terraced structure, wherein the second module comprises vertical wires connecting the overhang portions of the terraced structure of the second module to a top dielectric layer of the first module underneath the second module, and the insulation layer of the first module further includes through-insulation vias (TIVs) connecting the top dielectric layer to a bottom dielectric layer through the insulation layer, such that the dies of the second module are coupled to the bottom dielectric layer of the first module through the top dielectric layer and TIVs.

### CROSS-REFERENCE TO RELATED APPLICATIONS

This application is a continuation-in-part of U.S. patent application Ser. No. 18/884,172 filed Sep. 13, 2024, the contents of which are incorporated by reference.

### BACKGROUND

The escalating need for data processing power necessitates the ability to perform more computations in a smaller space while consuming less energy. In traditional two-dimensional (2D) chip designs, enhancing processing capabilities typically requires expanding the chip's size and energy consumption. However, three-dimensional (3D) designs, also known as vertical integration, have become an effective alternative. These 3D packaging structures enhance the number of functions per unit area while maintaining or even reducing energy usage, all within the same or a reduced footprint. Consequently, electronic devices can be packaged more compactly. A 3D integrated circuit (3DIC) is created by stacking various chips or wafers on top of one another within a single enclosure. The individual chips within this enclosure are linked through methods such as through-silicon vias (TSVs) and micro-bumps or through hybrid bonding technologies.

However, as the need for high performance computing grows, so does the number of layers in 3D packaging. For example, the bandwidth and storage capacity demand for computer memory (e.g., high bandwidth memory is anticipated to grow by two to threefold with each new generation. Due to these escalating requirements, the number of memory layers is expected to reach a high of 12 or even extend up to 16 layers (or tiers). However, if a terraced structure includes more than four tiers of core (e.g., memory) dies and passive (e.g., TSV) dies, there are other potential challenges to meet such escalating requirements, for example, the lack of proper bonding between the dies vertically and possibility of die cracking when the stacked structure exceeds four tiers given the current technologies for die thinning and bumping processes.

Therefore, there is a need for a semiconductor device (e.g., memory unit, logic chip unit, or a combination thereof) with improved 3D stacking packaging and a method for fabricating the same to address the issues and enable stable stacked structures with more than four tiers/layers of core dies including logic dies and/or memory dies.

Furthermore, other desirable features and characteristics will become apparent from the subsequent detailed description and the appended claims, taken in conjunction with the accompanying drawings and this background of the disclosure.

### BRIEF DESCRIPTION OF THE DRAWINGS

The accompanying drawings serve to provide an understanding of non-limiting aspects. Further non-limiting aspects and many of the intended advantages will become apparent directly from the following detailed description. The elements and structures shown in the drawings are not necessarily shown to scale relative to each other. Like reference numerals refer to like or corresponding elements and structures. Non-limiting aspects described herein will be better understood by one of ordinary skill in the art from the following detailed description and in conjunction with the drawings, in which:

FIG. 1 shows a schematic diagram of a cross-sectional view of a conventional high bandwidth memory 3D packaging structure;

FIG. 2 shows a schematic diagram illustrating a cross-sectional view of an alternative 3D packaging structure including active dies without through-silicon vias (TSVs) and separate passive dies that contain TSVs;

FIG. 3A shows a schematic diagram illustrating a perspective view of a terraced memory structure with 15 tiers of memory dies and TSV dies arranged side-by-side horizontally;

FIG. 3B shows a block diagram of first four tiers of a broken terraced memory structure having more than four tiers of active dies and passive dies.

FIG. 4 shows a schematic diagram illustrating a cross-sectional view of a non-limiting semiconductor device according to various aspects of the present disclosure;

FIG. 5 shows a schematic diagram illustrating a cross-sectional view of another non-limiting semiconductor device according to various aspects described herein;

FIG. 6 shows a schematic diagram illustrating a cross-sectional view of a non-limiting semiconductor device with four modules according to various aspects described herein;

FIG. 7 shows a schematic diagram illustrating respective routing paths of the plurality of dies of the modules stacked vertically in the semiconductor device and a layout of the conductive pads of a routing layer according to various aspects described herein;

FIG. 8 shows a schematic diagram illustrating a cross-sectional view of another non-limiting semiconductor device with four modules according to various aspects described herein;

FIG. 9 shows a schematic diagram illustrating a cross-sectional view of a non-limiting semiconductor device according to various aspects described herein;

FIG. 10 shows a schematic diagram illustrating a cross-sectional view of another non-limiting semiconductor device according to various aspects described herein;

FIG. 11 shows a schematic diagram illustrating a cross-sectional view of yet another non-limiting semiconductor device according to various aspects described herein;

FIG. 12 shows a schematic diagram illustrating a cross-sectional view of yet another non-limiting semiconductor device according to various aspects described herein;

FIG. 13 shows a schematic diagram illustrating a cross-sectional view of an alternative semiconductor device according to various aspects described herein;

FIG. 14 shows a flow chart illustrating a method for fabricating a semiconductor device according to various aspects described herein;

FIG. 15 shows a flow chart illustrating a part of processes of a step of the method shown in FIG. 14;

FIG. 16 shows a flow chart illustrating other part of processes of a step of the method shown in FIG. 14;

FIG. 17 shows a schematic diagram of a module fabricated through a method according to an aspect of the present disclosure before assembling into a semiconductor device; and

FIG. 18A shows a cross-sectional view of a second module when a known good module (KGM) step is carried out when preparing a first module on the second module during a sequential fanout RDP build-up module stacking process;

FIG. 18B shows a top view of the enlarged portion of the second module;

FIG. 19 shows a process of forming a top dielectric layer of a first module after performing a KGM test;

FIGS. 20A to 20D show schematic diagrams for fabricating a plurality of dies according to various aspects described herein.

### DETAILED DESCRIPTION

Aspects described below in the context of a method are analogously valid for the respective element, device, apparatus, or system, and vice versa. Furthermore, it will be understood that the aspects described below may be combined, for example, a part of one aspect may be combined with a part of another aspect, and a part of one aspect may be combined with a part of another aspect.

It should be understood that the singular terms “a”, “an”, and “the” include plural references unless context clearly indicates otherwise. Similarly, the word “or” is intended to include “and” unless the context clearly indicates otherwise.

It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Approximating language, as used herein throughout the specification and claims, may be applied to modify any quantitative representation that could permissibly vary without resulting in a change in the basic function to which it is related. Accordingly, a value modified by a term or terms, such as “about,” “substantially”, is not limited to the precise value specified but within tolerances that are acceptable for operation of the aspect for an application for which it is intended. In some instances, the approximating language may correspond to the precision of an instrument for measuring the value.

The term “exemplary” may be used herein to mean “serving as an example, instance, or illustration”. Any aspect or design described herein as “exemplary” is not necessarily to be construed as preferred or advantageous over other aspects or designs.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The term “first”, “second”, “third” detailed herein are used to distinguish one element from another similar element and may not necessarily denote order or relative importance, unless otherwise stated. For example, a first transaction data, a second transaction data may be used to distinguish two transactions based on two different foreign currency exchange.

The term “computing device” may be used herein to mean any suitable device and/or system such as, by way of example and not as a limitation, a personal computer, a laptop, a game console, a mobile phone and the like.

As used herein, the term “connect/connected/connection” may refer to a wired or wireless communication link formed between electronic devices that enables data transmission.

The term “processor” as used herein may be understood as any kind of entity that allows handling data. The data may be handled according to one or more specific functions executed by the processor or embedded controller. Further, a processor or embedded controller as used herein may be understood as any kind of circuit, e.g., any kind of analog or digital circuit. A processor or an embedded controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, embedded controller, or logic circuit. It is understood that any two (or more) of the processors, embedded controllers, or logic circuits detailed herein may be realized as a single entity with equivalent functionality or the like, and conversely that any single processor, embedded controller, or logic circuit detailed herein may be realized as two (or more) separate entities with equivalent functionality or the like.

The term “memory” detailed herein may be understood to include any suitable type of memory or memory device, e.g., a hard disk drive (HDD), a solid-state drive (SSD), a flash memory, etc.

As mentioned above, three-dimensional (3D) designs, also known as vertical integration, have become an effective alternative to traditional 2D chip designs for enhancing processing capabilities. These 3D packaging structures enhance the number of functions per unit area while maintaining or even reducing energy usage, all within the same or a reduced footprint. Consequently, electronic devices can be packaged more compactly.

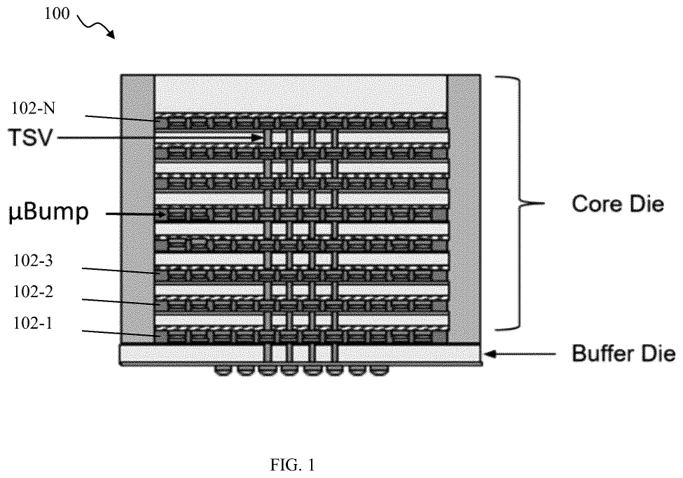

FIG. 1 shows a schematic diagram of a conventional 3D memory device 100. The memory device may be a high bandwidth memory (HBM) which is a current industrial example of utilizing 3DIC packaging of a memory unit. A 3DIC is created by stacking various chips or wafers on top of one another within a single enclosure. The individual chips (i.e., memory dies or core dies) are stacked vertically and integrated into multiple tiers 102-1, 102-2, 102-3, . . . , 102-N within this enclosure. The individual chips are linked through chip integrated through-silicon vias (TSVs) and micro-bumps (μ-bump) or through hybrid bonding technologies. The 3D vertical stacking method shortens the distances between the layers of dies within the memory unit, enabling quicker data transfer between them while using less power. HBM's exceptional performance is derived from vertically stacking multiple chips, which enables high-performance computing. This is due to benefits like broad input/output interfaces, reduced power requirements, and a smaller physical footprint.

However, the integration of multiple tiers of memory dies stacked vertically introduces significant technical challenges and cost implications. As incorporating TSVs into each memory die for data transmission and introducing the TSV fabrication process into active dies, such as those used for logic or memory, are essential, this can lead to reduced production yields, increased die size and increased manufacturing costs. Additionally, the space required for TSVs on every core die can limit circuit design options, amplify production costs and potentially impair device performance. These challenges pose limitations on the scalability of stacked memory technologies, impacting their feasibility for expanding to accommodate more tiers in future designs.

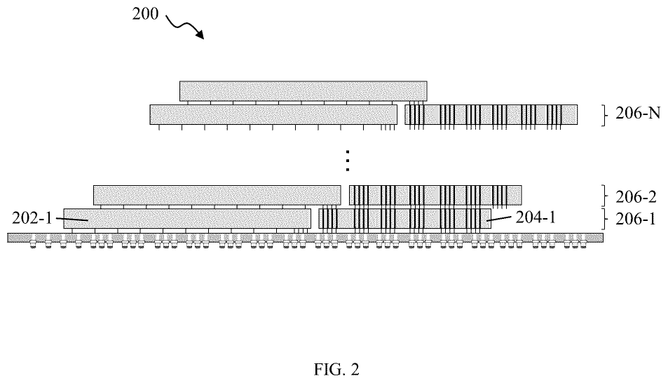

A solution to these challenges includes using an active die without TSVs alongside a separate passive die that contains TSVs for data transfer. FIG. 2 shows a schematic diagram illustrating a cross-sectional view of an alternative 3D packaging structure 200 including active dies without TSVs and separate passive dies that contain TSVs. An active die (e.g., a first active die 202-1) and a passive die (e.g., a first passive die 204-1) are assembled side-by-side horizontally to create a single layer or tier (e.g., a first tier 206-1) while multiple such tiers 206-1, 206-2, . . . , 206-N are stacked vertically into N tiers and terraced (i.e., partially overlaps or laterally offset from each other) to form the alternative 3D packaging structure 200. This may mitigate the issues associated with TSV integration in active dies while benefiting from the advantages of 3D packaging.

However, as the need for high performance computing grows, so does the number of layers in 3D packaging. For example, the bandwidth and storage capacity demand for memory is anticipated to grow by two to threefold with each new generation. Due to these escalating requirements, the number of memory layers is expected to reach a high of 12 or even extend up to 16 layers (or tiers). However, there are other challenges in creating reliable and stable stacked terraced structures with more four tiers of active dies and passive dies to meet such escalating requirements, given the current technologies for die thinning and bumping processes.

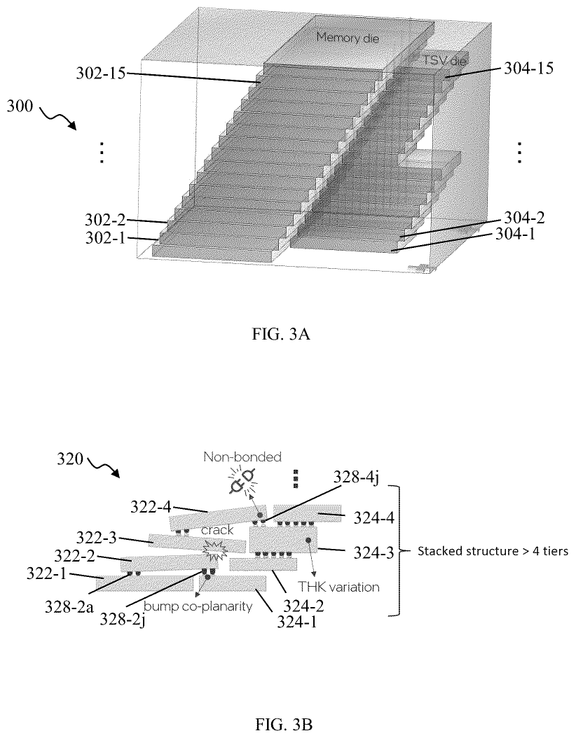

FIG. 3A shows a schematic diagram illustrating a perspective view of a terraced memory structure 300 with 15 tiers of memory dies 302-1, 302-2, . . . , 302-15 and TSV dies 304-1, 304-2, . . . , 304-15 arranged side-by-side horizontally. It is noted that, given the current technologies for die thinning and bumping processes, there could be a lack of proper bonding between the dies vertically and possibility of die cracking when the stacked structure exceeds four tiers of active dies and passive dies. FIG. 3B shows a block diagram of first four tiers of a broken terraced memory structure 320 having more than four tiers of active dies and passive dies. When the stacked structure 320 has more than four tiers, there may be a lack of proper bonding, for example, at a bump 328-4j between the fourth active die 322-4 and the third passive die 324-3. There may also be a lack of precision in thickness of die resulting in variations in the die thickness. For example, a third passive die 324-3 is thicker whereas a second passive die 324-2 is thinner than first and fourth passive dies 324-1, 324-4). There may be a lack of precision in bump size resulting in height variations and co-planarity issues. Such height variations and co-planarity issues can accumulate as more tiers are stacked, and also increase the possibility of lacking proper bonding and die cracking. For example, a bump 328-2a connecting first to second active dies 322-1, 322-2 has a different size from that of another bump 328-2j connecting a second active die 322-2 to a first passive die 324-1. This results in the second active die 322-2 slanting upward at one edge, potentially pressing the third active die 322-3 and causing a crack in the second or third active die 322-2, 322-3.

Various non-limiting aspects described herein seek to provide an advantageous and structurally stable and reliable semiconductor device. The semiconductor device may include two or more modules stacked vertically on one another, each module (e.g., base, middle, top modules) having a plurality of dies (e.g., four dies) stacked vertically within an insulation (molding) layer of the module. The base module which serves as a base on which other modules are vertically stacked may contain a bottom redistribution layer with vertical interconnects (e.g., conductive pads and lines) with bottom bumps protruding away (e.g., downward) from the bottom redistribution layer for connecting to an external substrate or interposer.

Each module contains a top RDL (except no top RDL on the top module), a plurality of dies (e.g., four dies) stacked using die attach film (DAF). The plurality of dies are laterally offset from each other to form a terraced or staggered structure within each module; each die higher than a lowest die among the plurality of dies within each module forms an overhang portion. Each module may further include vertical conductive wires that connect respective overhang portions to a redistribution layer directly underneath the plurality of dies (e.g., a top redistribution layer of another module underneath the module for modules that are stacked without bumps or a bottom redistribution layer of the module for modules that are stacked with bumps). The vertical conductive wire material can be gold (Au) or copper (Cu). Additionally, the insulation layer of each module may include a plurality of through-insulation vias (TIVs). The TIVs may be made of Cu by electroplating or Cu pillar. Each of the plurality of TIVs of the module is configured to be coupled (e.g., electrically connected) to another die, another vertical wire or another TIV of another module that is stacked vertically on the module. By stacking multiple modules in such manner, the dies of all modules (e.g., middle and top modules) higher than a lowest module (e.g., base module) within the semiconductor device are coupled (e.g., electrically connected) down to the bottom RDL of the lowest module, for example, through the connecting wires and TIVs, and a structurally stable and reliable semiconductor device with more than 4 tiers of dies can be achieved. For example, the top RDL includes routing layers to electrically connect vertical conductive wires of one module to a plurality of TIVs of another module immediately below the one module.

In various aspects, the top RDL design varies with module level for module-to-module connection. The modules may be vertically stacked on one another through module micro-bumps (μ-bumps) to form the semiconductor device. The modules may include a bottom RDL with the μ-bumps. Alternatively, each module may be vertically stacked on the top dielectric layer of another module to form the semiconductor device.

The semiconductor device and a method of fabricating the same described herein provide excellent scalability and low cost solution without bumping process for active die stacking and using modules for 3D stacking to meet high number of tiers requirements up to 16 dies and beyond; excellent joint yield by resetting the joint surface as flat as possible for module-to-module assembly and prevent cold joint risk from accumulated variations of terraced stacking up to 4 tiers and beyond; and also enhanced mechanical performance by stacking with modules and top RDLs as a stress buffer layer.

As used herein, the term “semiconductor device” may refer to a component such as a memory unit or a logic chip unit or a combination of both in computing systems, responsible for storing and processing digital data, respectively. In the context of a memory unit, it may play a pivotal role in facilitating rapid access to information during computing tasks, bridging the gap between processing units and long-term storage devices. Memory units may encompass both volatile types, such as RAM, which offer fast access speeds but require continuous power to maintain data, and non-volatile types like read-only memory (ROM) and flash memory, which retain data even without power. The memory unit may include a high bandwidth memory unit in advanced computing systems. In the context of a logic chip unit, it may be responsible for executing instructions, performing logical operations and data manipulation within the systems. These units typically serve as the core processing such as central processing units (CPUs), graphics processing units (GPUs), or application-specific integrated circuits (ASICs). A semiconductor device may include multiple logic chips and memory units working in tandem to process and execute complex algorithms efficiently.

The term “dielectric layer” may refer to a protecting layer or film that is made of dielectric material such as polyimide coated on a conductive element (e.g., die) to shield the conductive element from the external environment or another conductive element. In various aspects below, such dielectric layer, where applicable, may refer to a redistribution layer (RDL) coupled to a die or a module, and includes conductive lines (e.g., vertical interconnects or routing layer with layer of wiring for lateral connections) for connecting the die or module to other conductive elements such another die, another module, another RDL, a substrate and an interposer.

The term “insulation layer” may refer to a molding layer made of a material with insulating properties, encapsulating and isolating the components of a module such as dies, wires and TIVs to prevent unintended electrical connections or short circuits, ensure proper functions and interconnections of the components and also provide structural support of the module. Such molding layer may be formed by filling the entire module with mold resin or molded underfill (MUF).

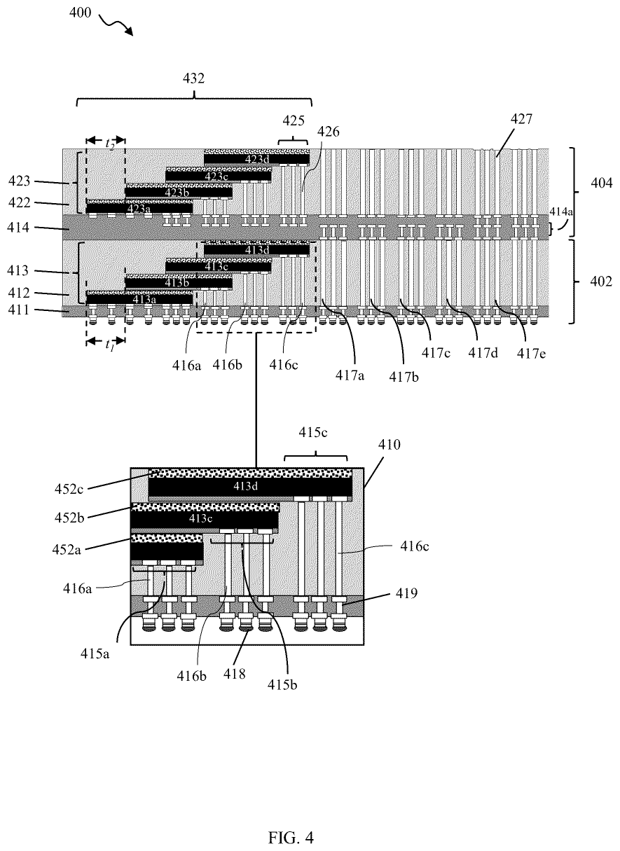

FIG. 4 shows a schematic diagram illustrating a cross-sectional view of a non-limiting semiconductor device 400 according to various aspects described herein. Inset 410 of FIG. 4 shows an enlarged portion of the semiconductor device 400. The semiconductor device 400 may include two modules stacked vertically on one another: a first module (e.g., base module) 402 and a second module (e.g., top module) 404. The first module 402 may include a (first) bottom dielectric layer 411, a first insulation layer 412 on the bottom dielectric layer 411, a plurality of first dies 413 stacked vertically within the first insulation layer 412 using die attach films (DAFs) (e.g., DAF 452a, 452b, 452c) and a (first) top dielectric layer 414 on the first insulation layer 412. The bottom dielectric layer 411 and the top dielectric layer 414 may be a bottom redistribution (RDL) layer and a top RDL, respectively.

The plurality of first dies 413 include four first dies 413a, 413b, 413c, 413d. It is appreciated that the plurality of first dies include any number of first dies larger than two, or 1^{st} to Nth first dies where N≥2, preferably N≤4. The plurality of first dies 413 are stacked vertically on one another within the first insulation layer 412 and are laterally offset from each other. Due to the vertical stacking and lateral offsets, each first die (e.g., first dies 413b, 413c, 413d) that is higher than (i.e., stacked on or above) a lowest first die 413a among the plurality of first dies 413 forms a respective first overhang portion (e.g., first overhang portions 415a, 415b, 415c of the plurality of first dies 413. Each higher first die is shifted from a lower first die with a pre-determined lateral displacement along a same lateral direction, forming a terrace structure. The lateral displacements t₁ of different higher first dies of the plurality of first dies 413 may be same or different.

The first module 402 may further include first vertical conductive wires (e.g., first vertical conductive wires 416a, 416b, 416c connecting the respective first overhang portions 415a, 415b, 415c of the plurality of first dies 413 to the bottom dielectric layer, such that the first dies 413b, 413c, 413d are coupled (e.g., connected) to the bottom dielectric layer 411 through the first vertical conductive wires. The lowest first die 413a may be coupled (e.g., connected) to the bottom dielectric layer 411, for example, through conductive pads and/or lines.

The first module 402 may also further include a plurality of first through-insulation vias (TIVs) (e.g., first TIVs 417a, 417b, 417c, 417d, 417e connecting the top dielectric layer 414 and the bottom dielectric layer 411 through the first insulation layer 412. In this example, the plurality of first dies are stacked vertically within the first insulation layer 412 at a peripheral or a (left) side portion of the first module 402, while the first insulation layer 412 may include the plurality of first TIVs at the other portion of the first module 402, e.g., a center portion and the opposite (right) side portion of the first module 402.

The second module 404 may stack vertically on the first module 402. The second module 404 may include a second insulation layer 422 on the first module 402, or more particularly, as illustrated in FIG. 4, on the top dielectric layer 414 of the first module 402, and a plurality of second dies 423 stacked vertically within the second insulation layer 422 on the top dielectric layer 414 using DAFs. Similar to the first module 402, the plurality of second dies 423 may include four second dies 423a-d. It is appreciated that the plurality of second dies 423 include any number of dies larger than two, or 1^{st} to Mth dies where M≥2, preferably M≤4). In some non-limiting aspects, the number of second dies (M) of the plurality of second die 412 within the second module may be different than the number of first dies (N) of the plurality of first dies 413 within the first module. In some other non-limiting aspects, as shown in FIG. 4, M may be the same as N. The plurality of second dies 423 are stacked vertically on one another within the second insulation layer 422 and are laterally offset from each other. Due to the vertical stacking and lateral offsets, each second die (e.g., second dies 423b, 423c, 423d) that is higher than (i.e., stacked vertically on or above) a lowest second die (e.g., second die 423a) among the plurality of second dies 423 forms a respective second overhang portion of the plurality of second dies 423 (e.g., second overhang hang portion 425 of the second die 423d). Each higher second die is shifted from a lower second die with a pre-determined lateral displacement along a same lateral direction, forming a terrace structure. The lateral displacements t₂ of different higher second dies of the plurality of second dies 423 may be same or different. The lateral displacement t₂ of the plurality of second dies may be same or different from that of the plurality of first dies t₁.

The plurality of second dies may stack vertically within the second insulation layer 422 at the peripheral or (left) side portion of the second module 404, while the second insulation layer 422 may include the plurality of second TIVs at the other portion of the second module 404, e.g., the center portion and the opposite (right) side portion of the second module 404.

The second module 404 may further include second vertical conductive wires (e.g., vertical conductive wire 426) connecting the respective second overhang portions (e.g., second overhang portion 425) of the plurality of second dies 423 to the first module, for example, as illustrated in FIG. 4, the top dielectric layer 414 of the first module 402 on which the second module 404 is stacked vertically on such that the second dies 423b, 423c, 423d are coupled (e.g., connected) to the top dielectric layer 414. The lowest second die 423a of the second module 404 may be coupled (e.g., connected) to the top dielectric layer 414 of the first module 402, for example, through conductive pads or wires.

The second module 404 may further include a plurality of second TIVs (e.g., second TIV 427) connecting to a dielectric layer or redistribution layer underneath the insulation layer 422, through the second insulation layer 422, in this case, the top dielectric layer 414.

According to various aspects described herein, each of the plurality of first TIVs 417 is coupled (e.g., electrically connected) to one of the plurality of second dies 423 (e.g., second die 423a), one of the plurality of second vertical conductive wires (e.g., second vertical conductive wire 426) coupled (e.g., connected) to another one of the plurality of second dies 423 (e.g., 423b-d), or one of the plurality of second TIVs (e.g., second TIV 427) through the top dielectric layer 414, for example, through conductive pads and/wires of the top dielectric layer 414. According to this example, through the top dielectric layer 414, the lowest second die 423a may be coupled (e.g., connected) to the first TIV 417a; the second vertical conductive wires connecting to other second dies 423b, 423c, 423d may be coupled (e.g., connected) to other first TIVs 417b, 417c, 417d; and the plurality of second TIV (e.g., second TIV 427) may be coupled (e.g., connected) to yet another first TIVs (e.g., first TIV 417e), respectively.

Similarly, each of the plurality of second TIVs may be configured to connect to one of a plurality of third dies, one of a plurality of third vertical conductive wires, or one of a plurality of third TIVs of a higher module (e.g., third module) having such similar components, in a similar manner.

In one aspect, shown in FIG. 4, the top dielectric layer 414 may include two or more top RDL and include a routing layer 414a with top conductive lines connecting first top conductive pads at a first portion 432 of the top dielectric layer 414 on and to which the plurality of first and second dies 413, 423 are stacked and coupled (e.g., connected) at respective first ends and second top conductive pads at second portions at respective second ends so that the top conductive lines may route and provide lateral connections between components coupled (e.g., connected) to the top dielectric layer 414 at the first and second portions. In other words, through the routing layer 414a of the top dielectric layer 414, each of the plurality of first TIVs is coupled (e.g., connected) to one of the plurality of second dies 423 (e.g., second die 423a), one of the plurality of second vertical conductive wires (e.g., second vertical conductive wire 426) coupled (e.g., connected) to another one of the plurality of second dies 423 (e.g., 423b-d), or one of the plurality of second TIVs (e.g., second TIV 427).

Additionally, the bottom dielectric layer 411 may be a bottom RDL and further include a plurality of bottom bumps (e.g., bottom bump 418) protruding away (e.g., downward) from the bottom dielectric layer 411 configured to connect to a substrate or an interposer to which the first module 402 is coupled (e.g., attached) at a protruding end. The plurality of bottom bumps includes (i) one or more bottom bumps for connecting to the lowest first die 413a among the plurality of first dies 413 stacked vertically on and coupled (e.g., connected) to the bottom dielectric layer 411, (ii) a respective bottom bump for connecting to each of the first vertical conductive wires including first vertical conductive wires 416a, 416b, 416c which in turn is coupled (e.g., connected) to each of the other first dies 413b, 413c, 413d higher than the lowest first die 413a among the plurality of first dies 413, and (iii) a respective bottom bump for connecting to each of the plurality of first TIVs including first TIVs 417a, 417b, 417c, 417d, 417e, which in turn is coupled (e.g., connected) to each die (e.g., a second die) of a higher module(s) (e.g., a second module) stacked vertically on or above the first module 402 through the top dielectric layer 414. The bottom dielectric layer 411 may further include bottom conductive lines (e.g., bottom conductive line 419) within the bottom dielectric layer 411 each connecting to one of the plurality of bottom bumps, while the lowest first die 413a of the plurality of first dies 413, each of the plurality of first vertical conductive wires and each of the plurality of first TIVs are coupled (e.g., connected) to the respective bottom bumps through respective coupled/connected bottom conductive lines in the bottom dielectric layer 411. Consequently, each of the plurality of bottom bumps is coupled (e.g., connected) to at least one of the plurality of first dies 413, one of the plurality of first vertical conductive wires or one of the plurality of first TIVs, and when the first module is coupled (e.g., attached) to a substrate or interposer, the plurality of first dies and second dies 413, 423 and other dies of the higher module(s) (e.g., a third module) stacked vertically on the second module 404, if any, are all coupled (e.g., connected) to the substrate or interposer.

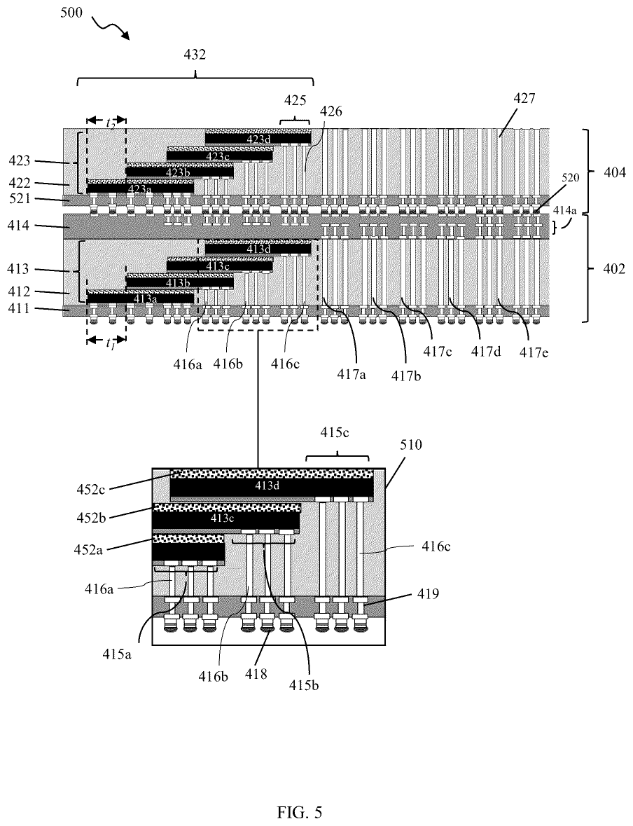

FIG. 5 shows a schematic diagram illustrating a cross-sectional view of another non-limiting semiconductor device 500 according to various aspects described herein. For purpose of brevity and to avoid unnecessary repetition, components that perform the same or equivalent functions across FIGS. 4 and 5 are designated using the same reference numerals. The description of components bearing the same reference numerals, as detailed in connection with FIG. 4, may be omitted or may not be repeated in detail in connection with FIG. 5. However, where applicable, additional details, specific differences, or unique aspects relevant to the particular component in FIG. 5 will be described and highlighted as follows.

The semiconductor device 500 may include two modules stacked vertically on one another: a first module (e.g., base module) 402 and a second module (e.g., top module) 404. The first module 402 may include a (first) bottom dielectric layer 411 (e.g., a bottom RDL), a first insulation layer 412 on the bottom dielectric layer 411, a plurality of first dies 413 with the first insulation layer 412 and a (first) top dielectric layer 414 (e.g., a top RDL) on the first insulation layer 412.

The first module 402 may further include first vertical conductive wires (e.g., first vertical conductive wires 416a, 416b, 416c connecting the respective first overhang portions 415 of the plurality of first dies 413 to the bottom dielectric layer, such that the first dies 413b, 413c, 413d are connected to the bottom dielectric layer 411 through the first vertical conductive wires. The lowest first die 413a may be connected to the bottom dielectric layer 411, for example, through conductive pads and/or lines. The vertical conductive wire material can be gold (Au) or copper (Cu).

The first module 402 may also further include a plurality of first TIVs (e.g., first TIVs 417a, 417b, 417c, 417d, 417e connecting the top dielectric layer 414 and the bottom dielectric layer 411 through the first insulation layer 412. In this example, the plurality of first dies are stacked vertically within the first insulation layer 412 using DAFs at a peripheral or a (left) side portion of the first module 402, while the first insulation layer 412 may include the plurality of first TIVs at the other portion of the first module 402, e.g., a center portion and the opposite (right) side portion of the first module 402.

The second module 404 may stack vertically on the first module 402. In this example, the second module 404 may include a second bottom dielectric layer 521 (e.g., a bottom RDL), a second insulation layer 422 on the second bottom dielectric layer 521 and a plurality of second dies 423 stacked vertically within the second insulation layer 422 on the second bottom dielectric layer 521 using DAFs. The second bottom dielectric layer 521 may be a (second) bottom redistribution (RDL) layer.

The second module 404 may further include second vertical conductive wires (e.g., second vertical conductive wire 426) connecting the respective second overhang portions (e.g., second overhang portion 425) of the plurality of second dies 423 to the second bottom dielectric layer 521 such that the second dies 423b, 423c, 423d are connected to the second bottom dielectric layer 521. The lowest second die 423a of the second module 404 may be connected to the second bottom dielectric layer 521, for example, through conductive pads or wires.

The second bottom dielectric layer 521 may further include a plurality of second bottom bumps (e.g., second bottom bump 520) protruding away (e.g., downward) from the second bottom dielectric layer 521 at a protruding end. The plurality of second bottom bumps are positioned between two modules, i.e., the bottom of the second module to the top of the first module, and configured the two modules, thus they may be referred to as “module micro-bumps” or “module μ-bump”. As shown in FIG. 5, the second module 404 is stacked vertically on the first module 402 by attaching the plurality of second bottom bumps onto the top dielectric layer 414 of the first module 402. The plurality of second bottom bumps may include (i) one or more bottom bumps for connecting to the lowest second die 423a among the plurality of second dies 423 to the top dielectric layer 414, (ii) a respective bottom bump for connecting to each of the second vertical conductive wires, which in turn is connected to each of the other second dies 423b, 423c, 423d higher than the lowest second die 423a among the plurality of second dies 423, to the top dielectric layer 414, and (iii) a respective bottom bump for connecting to each of the plurality of second TIVs (if any), which in turn is connected to each die (e.g., a third die) of a higher module(s) (e.g., a third module) stacked vertically on or above the second module 404, to the top dielectric layer 414. The second bottom dielectric layer 521 may further include second bottom conductive lines within the second bottom dielectric layer 521 each connecting to one of the plurality of second bottom bumps, while the lowest second die 423a of the plurality of first dies 423, each of the plurality of second vertical conductive wires and each of the plurality of second TIVs are connected to the respective second bottom bumps through respective connected second bottom conductive lines in the second bottom dielectric layer 521.

Consequently, each of the plurality of first TIVs is electrically connected to one of the plurality of second dies 423 (e.g., second die 423a), one of the plurality of second vertical conductive wires (e.g., second vertical conductive wire 426) connected to another one of the plurality of second dies 423 (e.g., 423b-d), or one of the plurality of second TIVs (e.g., second TIV 427) through the second bottom dielectric layer 521, more particularly, through the top dielectric layer 414 and a respective connected second bottom bump of the second bottom dielectric layer 521.

Similarly, each of the plurality of second TIVs may be configured to connect to one of a plurality of third dies, one of a plurality of third vertical conductive wires, or one of a plurality of third TIVs of a higher module (e.g., third module) having such similar components, in a similar manner.

The top dielectric layer 414 may include two or more top RDL and include a routing layer 414a with top conductive lines connecting first top conductive pads at a first portion 432 of the top dielectric layer 414 on and to which the plurality of first and second dies 413, 423 are stacked and connected at respective first ends and second top conductive pads at second portions at respective second opposite ends so that the top conductive lines may route and provide lateral connections between components connected to the top dielectric layer 414 at the first and second portions. In such case, through the routing layer 414a of the top dielectric layer 414 and a connected respective bottom bump of the second bottom dielectric layer 521, each of the plurality of first TIVs is connected to one of the plurality of second dies 423 (e.g., second die 423a), one of the plurality of second vertical conductive wires (e.g., second vertical conductive wire 426) connected to another one of the plurality of second dies 423 (e.g., 423b-d), or one of the plurality of second TIVs (e.g., second TIV 427).

Additionally, the bottom dielectric layer 411 may be a bottom RDL and further include a plurality of bottom bumps (e.g., bottom bump 418) protruding away (e.g., downward) from the bottom dielectric layer 411 configured to connect to a substrate or an interposer on which the first module 402 is attached at a protruding end. The bottom dielectric layer 411 may further include bottom conductive lines within the bottom dielectric layer 411 each connecting to one of the plurality of bottom bumps, while the lowest first die 413a of the plurality of first dies, each of the plurality of first vertical conductive wires and each of the plurality of first TIVs are connected to the respective bottom bumps through respective connected bottom conductive lines in the bottom dielectric layer 411 such that each of the plurality of bottom bumps is connected to at least one of the plurality of first dies 413, one of the plurality of first vertical conductive wires or one of the plurality of first TIVs, and when the first module is attached to a substrate or interposer, the plurality of first dies and second dies 413, 423 and other dies of the higher module(s) (e.g., a third module) stacked vertically on the second module 404, if any, are all connected to the substrate or interposer.

For purposes of avoiding clutter in the drawings, only some of the vertical conductive wires, TIVs and bumps are labelled in FIGS. 4 and 5. Additionally, to avoid further clutter, each vertical conductive wire shown may represent a vertical conductive wire of a set of one or more vertical conductive wires; each TIV shown may represent a TIV of a set of one or more TIVs. Each bump with conductive pads and conductive lines protruding away (e.g., downward) from the dielectric layer shown may represent a bump of a set of one or more bumps. Each die may include M interface ports (M being an integer>=1) (e.g., 1028 interface ports). For example, the first die 413b may include M interface ports. In such case, the vertical conductive wire 426 for connecting to the first overhang portion 415a of the first die 413b may be one vertical conductive wire of a set of M vertical conductive wires for connecting to the M interface ports of the first die 413b, and the other vertical lines of the set are not shown.

As used herein, the term “die” may refer to a logic die or a memory die. For example, a logic die may be included in a logic chip in the context of a CPU chip unit or module that handles primary processing tasks or contains the main processing units (cores). A memory may be included in a memory chip unit containing the bulk of the memory cells and basic control circuits in the context of a DRAM memory unit or module. In various aspects described herein, the die may be used interchangeably with “core die” and “active die” and refer to a die or chiplet engaged in active operations including reading or writing data.

According to various aspects described herein, a semiconductor device may include more than two modules stacked vertically on one another simply by staking one or more middle module between the base and top modules. For example, a semiconductor device may include three modules stacked vertically on one another: a first module (e.g., base module), a second module (e.g., middle module) and a third module (e.g., top module). A semiconductor device may also include four or more modules stacked vertically on one another: a first module (e.g., base module), a second module (e.g., middle module), a third module (e.g., middle+1 module) and a fourth module (e.g., top module).

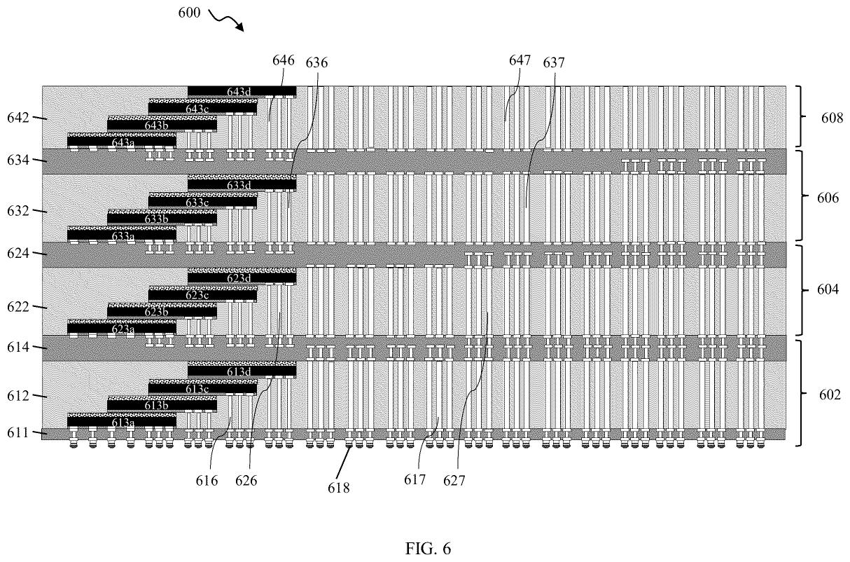

FIG. 6 shows a schematic diagram illustrating a cross-sectional view of a non-limiting semiconductor device 600 with four modules according to various aspects described herein. The semiconductor device 600 may include four modules stacked vertically on one another: a first module (e.g., base module) 602, a second module 604 (e.g., middle module), a third module 606 (e.g., middle+1 module) and a fourth module 608 (e.g., top module).

Each module may include an insulation layer (e.g., first insulation layer 612, second insulation layer 622, third insulation layer 632, fourth insulation layer 642) and a respective plurality of dies (e.g., first dies 613a, 613b, 613c, 613d, second dies 623a, 623b, 623c, 623d, third dies 633a, 633b, 633c, 633d, fourth dies 643a, 643b, 643c, 643d stacked vertically within each module using DAFs. In this example, each higher die is shifted from a lower die with a pre-determined lateral displacement along a same lateral direction, forming a terrace structure in each module.

The first module 602 may further include a (first) bottom dielectric layer 611 (e.g., a bottom RDL) to which the plurality of first dies is attached and a (first) top dielectric layer 614 (e.g., a top RDL) on the first insulation layer 612. The bottom dielectric layer 611 and the top dielectric layer 614 may be a bottom redistribution (RDL) layer and a top RDL, respectively.

The second module 604 is stacked vertically on the first module 602. The third module 606 is stacked vertically on the second module 604. The second module 604 and the third module 606 are both middle modules thus they may share similar or identical components (except top dielectric layers 624, 634). In particular, the plurality of second dies is stacked vertically within the second insulation layer 622 on the top dielectric layer 614. The second module 604 further includes a second top dielectric layer 624 on the second insulation layer 622. The plurality of third dies is stacked vertically within the third insulation layer 632 on the second top dielectric layer 624. The third module 606 further includes a third top dielectric layer 634 (e.g., a top RDL) on the third insulation layer 632. The fourth module 608 is stacked vertically on the third module 606. In particular, the plurality of fourth dies is stacked vertically within the fourth insulation layer 642 on the third top dielectric layer 634. Similarly, the second top dielectric layer 624 and the third top dielectric layer 634 may both be top RDL.

The plurality of dies of each module (e.g., modules 602, 604, 606, 608) are stacked vertically on one another within the respective insulation layer (e.g., insulation layers 612, 622, 632, 642) and are laterally offset from each other. Due to the vertical stacking and lateral offsets, each die that is higher than (i.e., stacked on or above) a lowest die (e.g., lowest first die 613a, lowest second die 623a, lowest third die 633a, lowest fourth die 643a) among the plurality of dies within each module forms a respective overhang portion of the plurality of dies.

Each module may further include respectively a plurality of vertical conductive wires (e.g., first vertical conductive wires (collectively 616), second vertical conductive wires (collectively 626), third vertical conductive wires (collectively 636) and fourth vertical conductive wires (collectively 646)) for connecting respective overhang portions of the plurality of dies to a dielectric layer underneath the respective plurality of dies or that the respective plurality of dies are stacked on. According to this example, the first vertical conductive wires 616 connects the respective first overhang portions of the plurality of first dies to the bottom dielectric layer 611 such that the first dies 613b, 613c, 613d higher than the lowest first die 613a are connected to the bottom dielectric layer 611; the second vertical conductive wires 626 connects the respective second overhang portions of the plurality of second dies to the top dielectric layer 614 of the first module 602 such that the second dies 623b, 623c, 623d are connected to the top dielectric layer 614; the third vertical conductive wires 636 connects the respective third overhang portions of the plurality of third dies to the second top dielectric layer 624 of the second module 604 such that the third dies 633b, 633c, 633d are connected to the second top dielectric layer 624; and the fourth vertical conductive wires 646 connects the respective fourth overhang portions of the plurality of fourth dies to the third top dielectric layer 634 of the third module 606 such that the fourth dies 643b, 643c, 643d are connected to the third top dielectric layer 634. The lowest first die 613a may be connected to the bottom dielectric layer 611; the lowest second die 623a may be connected to the top dielectric layer 614; the lowest third die 633a may be connected to the second top dielectric layer 624; and the lowest fourth die 643a may be connected to the third top dielectric layer 634, for example, through respective conductive pads and/or lines between the lowest die 613a, 623a, 633a, 643a and the dielectric layers 611, 614, 624, 634.

Each module may also include a respective plurality of through-insulation vias (TIVs) (e.g., first TIVs (collectively 617), second TIVs (collectively 627), third TIVs (collectively 637), fourth TIVs (collectively 647)) through the respective insulation layer to form connections between a top dielectric layer (or a top RDL) on top of the respective insulation layer, if any, and a bottom dielectric layer (or a bottom RDL) underneath the respective insulation layer. According to this example, the first module 602 may include a plurality of first TIVs connecting the top dielectric layer 614 and the bottom dielectric layer 611 through the first insulation layer 612; the second module 604 may include a plurality of second TIVs 627 connecting to the second top dielectric layer 624 on top of the second insulation layer 622 and the top dielectric layer 614 of the first module 602 underneath the second insulation layer 622; the third module 606 may include a plurality of third TIVs 637 connecting to the third top dielectric layer 634 on top of the third insulation layer 632 and the second top dielectric layer 624 of the second module 604 underneath the third insulation layer 632; and the fourth module 608 may include a plurality of fourth TIVs 647 connecting to the third top dielectric layer 634 of the third module.

According to various aspects described herein, the height of such unit module (e.g., first module) may be equal to or less than 200 μm excluding module μ-bumps. The dielectric layer (e.g., RDL) sandwiched between two modules among the four modules 602, 604, 606, 608 is configured to connect each TIV of a lower module to the dies, vertical conductive wires to the TIVs of a higher module stacked on the lower module so as to form connections between them, similar to that illustrated in FIGS. 4 and 5. According to this example, each of the plurality of third TIVs 637 of the third module 606 is electrically connected to one of the plurality of fourth dies (e.g., fourth die 643a), one of the plurality of fourth vertical conductive wires 646, or one of the plurality of fourth TIVs 647 through the third top dielectric layer 634, for example, through a routing layer including conductive pads and/wires of the top third dielectric layer 634 (e.g., third top RDL). Similarly, each of the plurality of third TIVs 637 of the third module 606 is connected to one of the plurality of fourth dies (e.g., fourth die 643a), one of the plurality of fourth vertical conductive wires 646, or one of the plurality of fourth TIVs 647 through the third top dielectric layer 634, for example, through a routing layer including conductive pads and/wires of the top third dielectric layer 634. Similarly, each of the plurality of second TIVs 627 of the second module 604 is electrically connected to one of the plurality of third dies (e.g., third die 633a), one of the plurality of third vertical conductive wires 636 connected to another one of the plurality of third dies (e.g., 633b-d), or one of the plurality of third TIVs 637 through the second top dielectric layer 624, for example, through a routing layer including conductive pads and/wires of the second top dielectric layer 624 (e.g., second top RDL). Similarly, each of the plurality of first TIVs 617 of the first module 602 is electrically connected to one of the plurality of second dies (e.g., second die 623a), one of the plurality of second vertical conductive wires 626 connected to another one of the plurality of second dies (e.g., 623b-d), or one of the plurality of second TIVs 627 through the top dielectric layer 614 (e.g., first top RDL), for example, through a routing layer including conductive pads and/wires of the top dielectric layer 614.

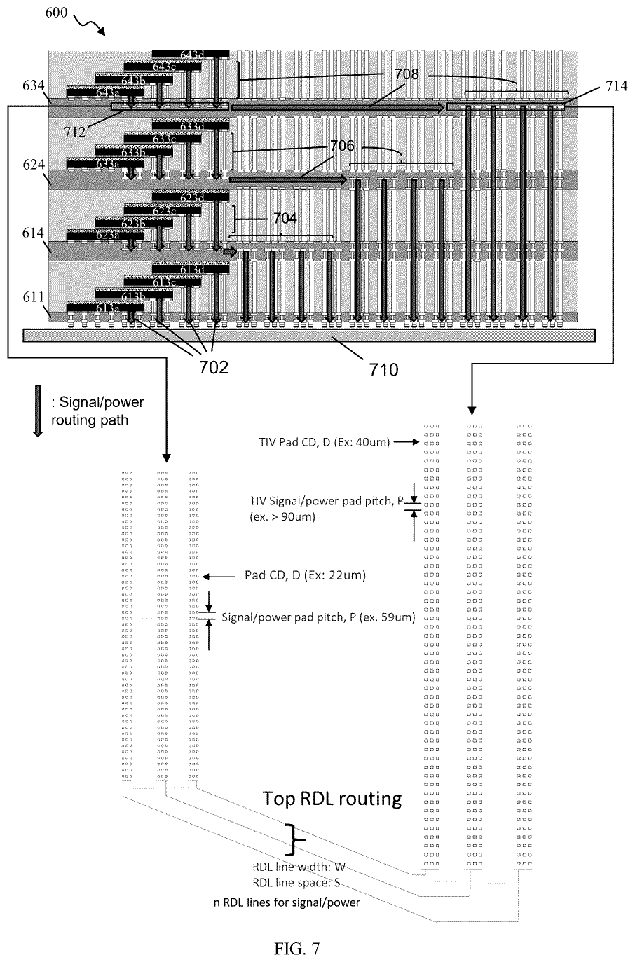

The plurality of dies in each module within the semiconductor device 600 are all connected to a bottom dielectric layer of the base module through respective routing paths. FIG. 7 shows a schematic diagram illustrating respective routing paths of the plurality of dies of the modules stacked vertically in the semiconductor device 600 and a layout of the conductive pads of a routing layer according to various aspects described herein. The semiconductor device is disposed on a substrate or a silicon (Si)/organic interposer 710. The contact and first vertical conductive wires between the plurality of first dies and the bottom dielectric layer 611 form respective first routing paths, illustrated by arrows 702, that connect and route the signal/powers of the plurality of first dies within the first module 602 in the way down to the bottom dielectric layer 611. The contacts and second vertical conductive wires connecting the plurality of second dies of the second module 604, the top dielectric layer 614 (e.g., conductive lines of the routing layer of the top dielectric layer 614), and the first TIVs of the first module 602 form respective second routing paths, illustrated by arrows 704, that connect and route the signal/power of each of the plurality of second dies within the second module 604 down to the bottom dielectric layer 611 of the first (base) module 602.

Similarly, the contacts and third vertical conductive wires connecting the plurality of third dies of the third module 606, the second top dielectric layer 624 (e.g., conductive lines of the routing layer of the second top dielectric layer 624), the second TIVs of the second module 604, and the top dielectric layer 614 (e.g., conductive lines of the routing layer of the top dielectric layer 614) and the first TIVs of the first module 602 form respective third routing paths, illustrated by arrows 706, that connect and route the signal/power of each of the plurality of third dies within the third module 606 down through the second module 604 to the bottom dielectric layer 611 of the first (base) module 602. The contacts and fourth vertical conductive wires connecting the plurality of fourth dies of the fourth module 608, the third top dielectric layer 634 (e.g., conductive lines of the routing layer of the third top dielectric layer 634) and the third TIVs of the third module 606, the second top dielectric layer 624 (e.g., conductive lines of the routing layer of the second top dielectric layer 624) the second TIVs of the second module 604, and the top dielectric layer 614 (e.g., conductive lines of the routing layer of the top dielectric layer 614), and the first TIVs of the first module 602 form respective fourth routing paths, illustrated by arrows 708, that connect and route the signal/power of each the of plurality of fourth dies within the fourth module 608 down through the second and third modules 604, 606 to the bottom dielectric layer 611 of the first (base) module 602.

Additionally, the bottom dielectric layer 611 may be a bottom RDL and further include a plurality of bottom bumps (collectively 618) protruding away (e.g., downward) from the bottom dielectric layer 611 configured to connect to a substrate or an interposer to which the first module 602 is attached at a protruding end. The plurality of bottom bumps includes (i) one or more bottom bumps for connecting to the lowest first die 613a among the plurality of first dies stacked vertically on and connected to the bottom dielectric layer 611, (ii) a respective bottom bump for connecting to each of the first vertical conductive wires 616 which in turn is connected to each of the other first dies 613b, 613c, 613d higher than the lowest first die 613a among the plurality of first dies, and (iii) a respective bottom bump for connecting to each of the plurality of first TIVs, which in turn is connected to each die (e.g., second die, third die, fourth die) of a higher module(s) (e.g., second module, third module, fourth module) stacked vertically on or above the first module 606 through a respective routing path (routing paths illustrated by arrows 704, 706, 708). The bottom dielectric layer 611 may further include bottom conductive lines within the bottom dielectric layer 611 each connecting to one of the plurality of bottom bumps, while the lowest first die 613a of the plurality of first dies, each of the plurality of first vertical conductive wires and each of the plurality of first TIVs are connected to the respective bottom bumps through respective connected bottom conductive lines in the bottom dielectric layer 611. Consequently, each of the plurality of bottom bumps is connected to at least one of the plurality of first dies, one of the plurality of first vertical conductive wires or one of the plurality of first TIVs, and when the first module 602 is attached to a substrate or interposer, the dies across all the modules in the semiconductor device 600 are all connected to the substrate or interposer.

Although FIG. 6 shows that the stack of dies within each module include four dies, it is appreciated that the stack of die in each module may include any number of dies larger than two, or 1^{st} to Nth first dies where N≥2, preferably N≤4. It is also appreciated that the plurality of first dies within the first module 602 may include any number of dies larger than two, or 1^{st} to Nth dies where N≥2, preferably N≤4); the plurality of second dies within the second module 604 may include any number of dies larger than two, or 1^{st} to Mth dies where M≥2, preferably M≤4); the plurality of third dies within the third module 606 may include any number of dies larger than two, or 1^{st} to Pth dies where P≥2, preferably P≤4); and the plurality of fourth dies within the fourth module 608 may include any number of dies larger than two, or 1^{st} to Rth dies where R≥2, preferably R≤4). In some non-limiting aspects, all among M, N, P and R may be equal. In some non-limiting aspects, some among M, N, P and R may be equal (e.g., M=N and P=R). In some non-limiting aspects, M, N, P and R may be all different. In one aspect, the first, second, third and fourth modules are built using an identical unit module (except top dielectric layers 614, 624, 634). In other words, the plurality of first dies, the first insulation layer 612, the first vertical conductive wires 616 and the plurality of first TIVs 617 of the first module 602 may be identical to the plurality of second dies, the second insulation layer 622, the second vertical conductive wires 626 and the plurality of second TIVs 627 of the second module 604 or those of the third and fourth modules 606, 608, including the lateral offsets of the plurality of dies and the layout and dimensions of the components. Alternatively, in other non-limiting aspects, the modules 602, 604, 606, 608 may not be identical, and the number of dies, the lateral offset of the dies and the layout of the components across different modules may be different. In various aspects, respective top dielectric layers (e.g., top RDL with routing layers) with different designs and connection layouts are attached on such unit modules used in different module levels to form the semiconductor device to ensure proper routing paths are formed ensuring the signal/power/data of each die of each module of a higher module level (e.g., second, third, fourth modules and beyond), can be all connected and transfer to the bottom dielectric layer 611 of the base module, through Cu TIVs.

In addition, the total RDL line of signal/power should be routed between pad and pad of signal/power for shortening the connections. In one aspect, the conductive lines in the routing layer of a top dielectric layer (e.g., top dielectric layers 614, 624, 634) may further include first conductive pads at respective first ends (e.g., first ends 712 of top dielectric layer 634) and second pads at respective second ends of the top conductive lines (e.g., second ends 714 of top dielectric layer 634); the first conductive pads respectively connected to the components of a higher module (e.g., a second module) such as the lowest second die 623a; the plurality of second vertical conductive wire and the plurality of second TIV of the second module 604 and the second conductive pads respectively connected to the plurality of TIVs of a lower module (e.g., a first module), such that the respective conductive lines which provide lateral connections between the first and second pads which in turn connects the respective components of the two modules.

According to various aspects described herein, the respective first conductive pads have a first predetermined size, the respective second pads have a second predetermined size, the respective top conductive lines have a predetermined space from one another and/or the respective conductive lines have a predetermined width according to the design rule shown in the following equation (1), wherein D is a diameter or size of the pad, P is the signal/power pad pitch or the space/spacing between the pads, n is the number of conductive lines (RDL lines) for signal/power, W is the width of the conducive line and S is the space/spacing between the conductive lines.

$$P - D \geq n ( S + W ) + S \qquad equation ( 1 )$$

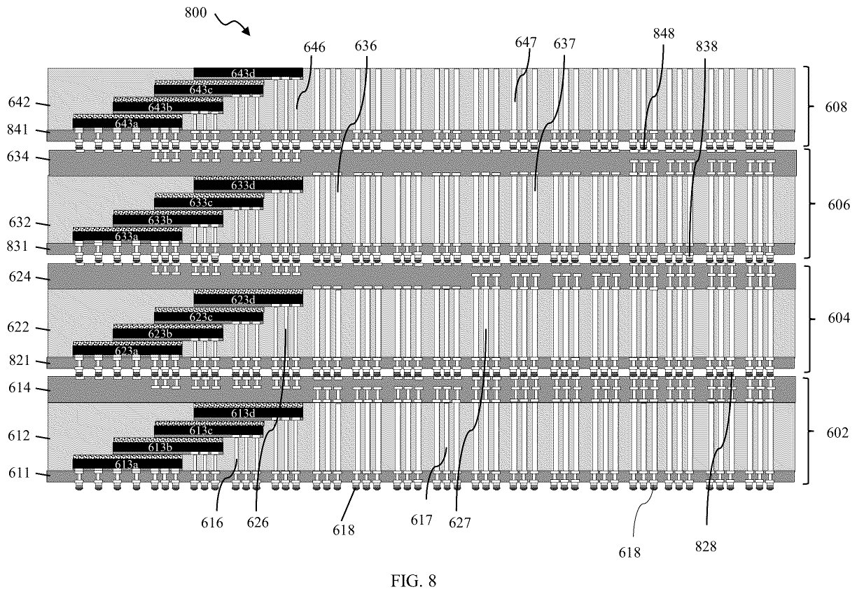

FIG. 8 shows a schematic diagram illustrating a cross-sectional view of another non-limiting semiconductor device 800 with four modules according to various aspects described herein. The semiconductor device 800 includes similar components with identical functions as those of the semiconductor device 600 of FIG. 6, except that there is a bottom dielectric layer (e.g., bottom RDL) on each higher module (e.g., middle modules 604, 606, top module 608) that is stacked vertically on a lower module and respective module μ-bump or bottom bumps (e.g., bottom bumps 828, 838, 848) for connecting the higher modules to the lower modules. For purpose of brevity and to avoid unnecessary repetition, components that perform the same or equivalent functions across FIGS. 6 and 8 are designated using the same reference numerals. The description of components bearing the same reference numerals, as detailed in connection with FIG. 6, may be omitted or may not be repeated in detail in connection with FIG. 8. However, where applicable, additional details, specific differences, or unique aspects relevant to the particular component in FIG. 8 will be described and highlighted as follows.

In this example, the semiconductor device 800 further includes second bottom dielectric layer 821 with a plurality of second bottom bumps (e.g., second bottom bump 828) protruding away (e.g., downward) from the second bottom dielectric layer 821 and connecting to the first module 602, third bottom dielectric layer 831 with a plurality of third bottom bumps (e.g., third bottom bump 838) protruding away (e.g., downward) from the third bottom dielectric layer 831 and connecting to the second module 604 and fourth bottom dielectric layer 841 with a plurality of fourth bottom bumps (e.g., fourth bottom bump 848) protruding away (e.g., downward) from the fourth bottom dielectric layer 841 and connecting to the third module 606, respectively. Similar to the bottom dielectric layer 611, the second, third and fourth bottom dielectric layer 821, 831, 841 may all be bottom RDL.

Similar to the plurality of bottom bumps 618 of the first module, the plurality of bottom bumps of the second, third and fourth modules 604, 606, 608 may include (i) bumps that connect to the respective lowest die among the respective pluralities of dies stacked vertically within the respective insulation layers, (ii) bumps for connecting to the respective vertical conductive wires within the modules, which in turn is connected to the other dies higher than the lowest die, and respective bottom bumps for connecting to the respective pluralities of TIVs within the modules.

As such, the routing paths of the plurality of second dies to connect to the bottom dielectric layer 611 of the first module (e.g., that shown by arrow 704) further include paths through respective second bottom bumps 828 of the second bottom dielectric layer 821 of the second module 604 connected to the plurality of second dies 623; the routing paths of the plurality of third dies to connect to the bottom dielectric layer 611 of the first module (e.g., that shown by arrow 706) further include paths through respective third bottom bumps 838 of the third bottom dielectric layer 831 of the third module 606 connected to the plurality of third dies and respective second bottom bumps 828 of the second bottom dielectric layer 821 of the second module connected to the second TIVs; and the routing paths of the plurality of fourth dies to connect to the bottom dielectric layer 611 of the first module (e.g., that shown by arrow 708) further include paths through respective fourth bottom bumps 848 of the fourth bottom dielectric layer 841 of the fourth module 608 connected to the plurality of fourth dies, respective third bottom bumps 838 of the third bottom dielectric layer 831 of the third module 606 connected to the third TIVs and respective second bottom bumps 828 of the second bottom dielectric layer 821 of the second module connected to second TIVs.

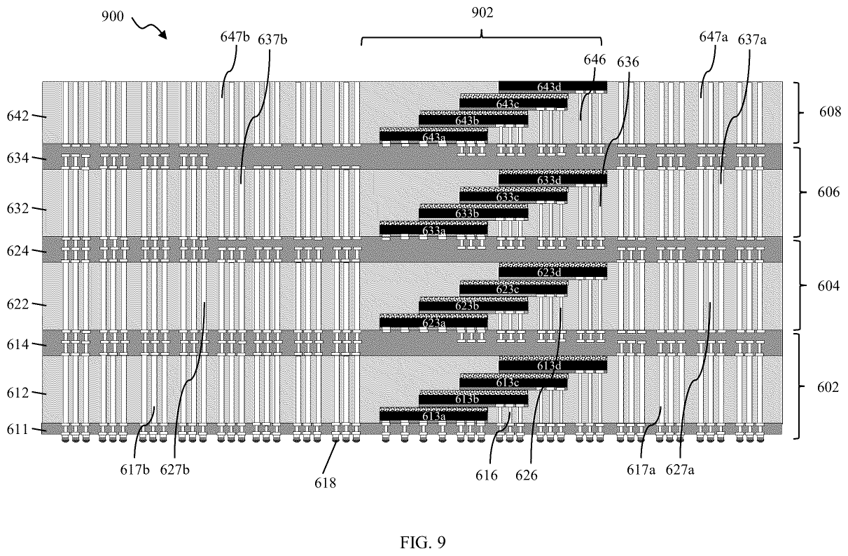

FIG. 9 shows a schematic diagram illustrating a cross-sectional view of a non-limiting semiconductor device 900 according to various aspects described herein. The semiconductor device 900 includes similar components with identical functions as those of the semiconductor device 600 of FIG. 6, except that the respective pluralities of dies are stacked at respective center portions 902 of the modules 602, 604, 606, 608 (instead of a peripheral or edge portion shown in FIGS. 4-6 and 8), while the respective pluralities of TIVs (e.g., first TIVs 617a, 617b, second TIVs 627a, 627b, third TIVs 637a, 637b, fourth TIVs 647a, 647b) are at the respective peripheral or edge portions of the modules surrounding the plurality of dies.

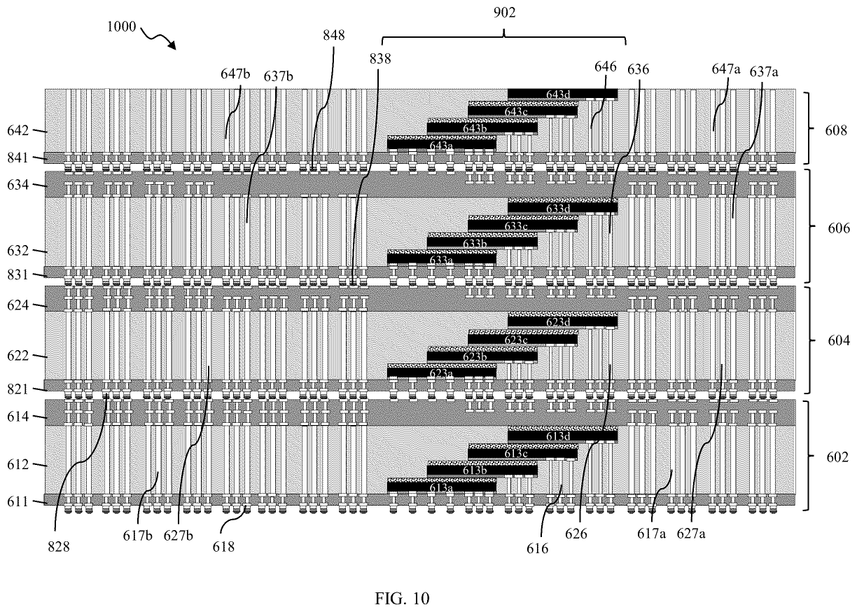

FIG. 10 shows a schematic diagram illustrating a cross-sectional view of another non-limiting semiconductor device 1000 according to various aspects described herein. The semiconductor device 1000 includes similar components with identical functions as those of the semiconductor device 800 of FIG. 8 with a bottom dielectric layer (e.g., bottom dielectric layers 821, 831, 841, which are bottom RDL) on each higher module (e.g., middle modules 604, 606, top module 608) that is stacked vertically on a lower module and respective module μ-bump or bottom bumps (e.g., bottom bumps 828, 838, 848) for connecting the higher modules to the lower modules, except that the respective pluralities of dies are stacked at respective center portions 902 of the modules 602, 604, 606, 608 (instead of a peripheral or edge portion shown in FIG. 8), while the respective pluralities of TIVs (e.g., first TIVs 617a, 617b, second TIVs 627a, 627b, third TIVs 637a, 637b, fourth TIVs 647a, 647b) are at the respective peripheral or edge portions of the modules surrounding the plurality of dies. As the dies are all stacked at the center portion, this may improve the structural integrity of the semiconductor device 900.

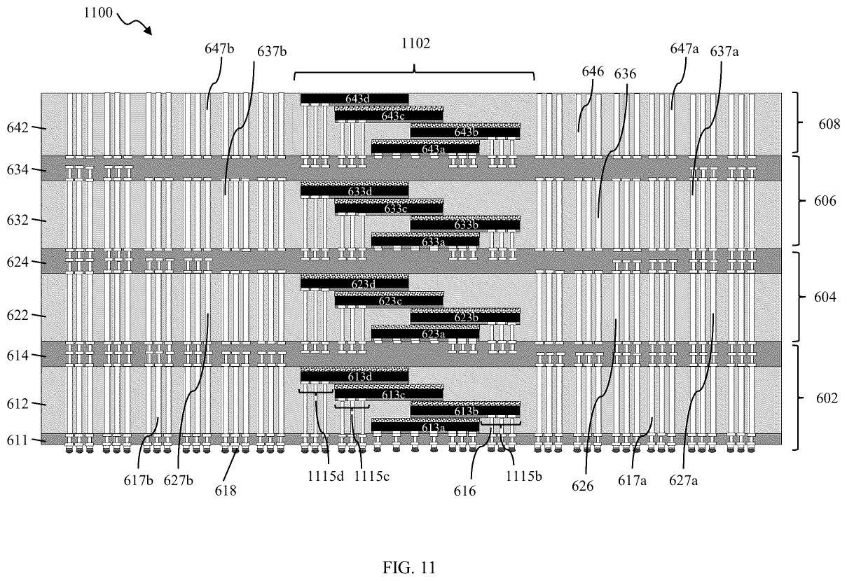

FIG. 11 shows a schematic diagram illustrating a cross-sectional view of yet another non-limiting semiconductor device 1100 according to various aspects described herein. The semiconductor device 1100 includes similar components with identical functions as those of the semiconductor device 600 of FIG. 6, except that the respective pluralities of dies are stacked with a staggered structure (instead of a terrace structure shown in FIGS. 4-6 and 8) at respective center portions 1102 of the modules 602, 604, 606, 608, while the respective pluralities of TIVs (e.g., first TIVs 617a, 617b, second TIVs 627a, 627b, third TIVs 637a, 637b, fourth TIVs 647a, 647b) are at the respective peripheral or edge portions of the modules surrounding the plurality of dies.

The plurality of first dies are stacked vertically on one another within the first insulation layer 412 and are laterally offset from each other. The higher first dies (e.g., first dies 613b 613c, 613d) may be shifted in opposite lateral directions so as to form a staggered structure closer to the center portion 1102 of the modules. For example, the first die 613b may shift from the lowest first die 613a along a right lateral direction, forming a respective first overhang portion 1115b on a right side of the plurality of first dies; the first die 613c may shift from the first die 613b along the opposite direction, i.e., a left lateral direction, forming a respective first overhang portion 1115c on a left side of the plurality of dies; while the first die 613d may shift further from the first die 613c also along the left lateral direction, forming a respective first overhang portion 1115d on a further left side of the plurality of dies.

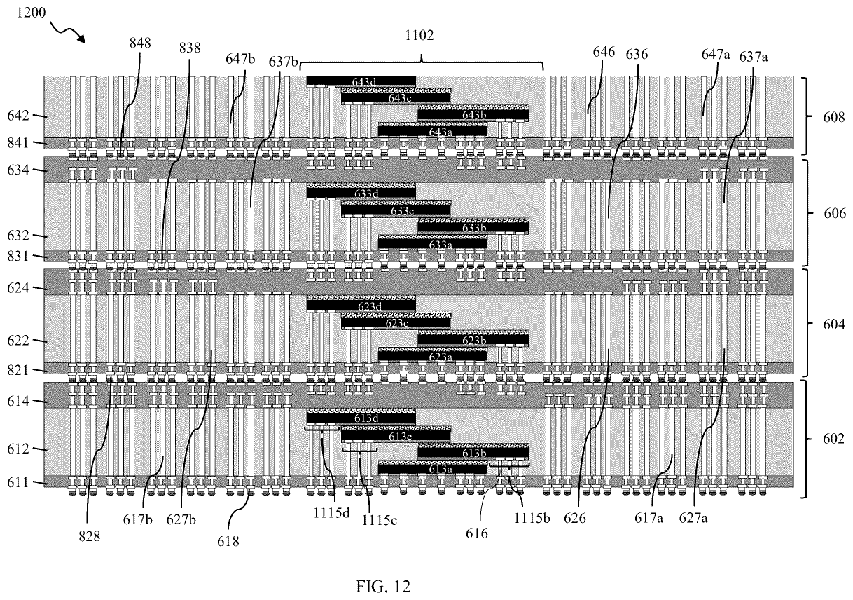

FIG. 12 shows a schematic diagram illustrating a cross-sectional view of yet another non-limiting semiconductor device 1200 according to various aspects described herein. The semiconductor device 1200 includes similar components with identical functions as those of the semiconductor device of FIG. 8 with a bottom dielectric layer (e.g., bottom dielectric layers 821, 831, 841, which are bottom RDL) on each higher module (e.g., middle modules 604, 606, top module 608) that is stacked vertically on a lower module and respective module μ-bump or bottom bumps (e.g., bottom bumps 828, 838, 848) for connecting the higher modules to the lower modules, except that the respective pluralities of dies are stacked with a staggered structure (instead of a terrace structure shown in FIGS. 8 and 9) at respective center portions 902 of the modules 602, 604, 606, 608, while the respective pluralities of TIVs (e.g., first TIVs 617a, 617b, second TIVs 627a, 627b, third TIVs 637a, 637b, fourth TIVs 647a, 647b) are at the respective peripheral or edge portions of the modules surrounding the plurality of dies.

It is noted that the staggered structure shown in FIGS. 11 and 12 are different from the terraced structures shown in FIGS. 4-6 and 8 where the dies are shifted along a same lateral direction, resulting the overhang portions extending further and further away from a center portion along the same side of the plurality of dies. As staggered structures have the plurality of dies stacked closer to the center portion 1102, they can further enhance the robustness and integrity of the stacks and modules.

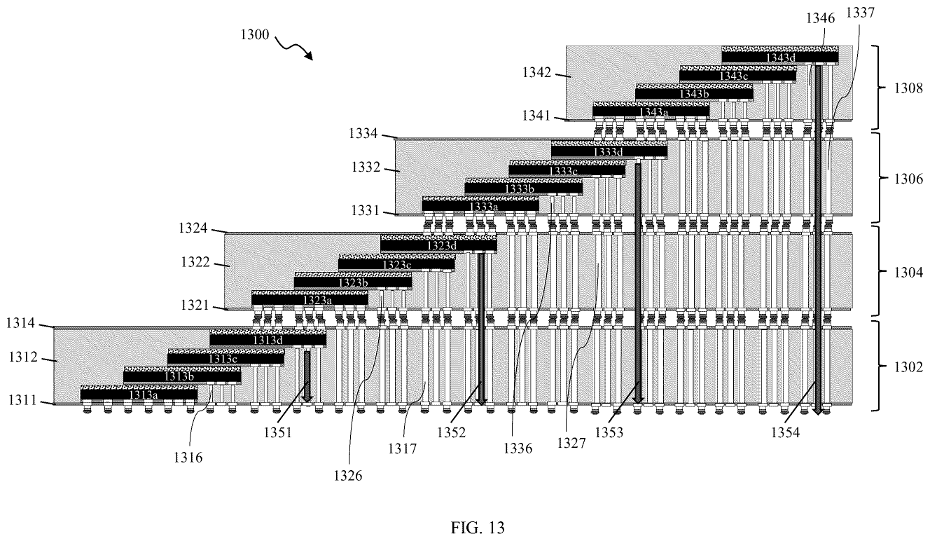

FIG. 13 shows a schematic diagram illustrating a cross-sectional view of an alternative semiconductor device 1300 according to various aspects described herein. The semiconductor device 1300 may include four modules stacked vertically on one another: a first module (e.g., base module) 1302, a second module 1304 (e.g., middle module), a third module 1306 (e.g., middle+1 module) and a fourth module 1308 (e.g., top module).

Each module may include a thin bottom dielectric layer (e.g., first bottom dielectric layer 1311, second bottom dielectric layer 1321, third bottom dielectric layer 1331, fourth bottom dielectric layer 1341) having a plurality of bumps configured to connect with a lower module, an insulation layer (e.g., first insulation layer 1312, second insulation layer 1322, third insulation layer 1332, fourth insulation layer 1342), a respective plurality of dies (e.g., first dies 1313a, 1313b, 1313c, 1313d, second dies 1323a, 1323b, 1323c, 1323d, third dies 1333a, 1333b, 1333c, 1333d and fourth dies 1343a, 1343b, 1343c, 1343d, and a thin top dielectric layer (e.g., first top dielectric layer 1314, second top dielectric layer 1324, third top dielectric layer 1334) except the top module 1308 may have a top dielectric layer. The plurality of dies are stacked vertically on one another within the respective insulation layer 1312, 1322, 1332, 1342 using DAFs and are laterally offset from each other along a same lateral direction, forming a terraced structure in each module. Due to the vertical stacking and lateral offsets, each die that is higher than (i.e., stacked on or above) a lowest die 1313a, 1323a, 1333a, 1343a among the plurality of dies within each module (e.g., modules 1302, 1304, 1306, 1308) forms a respective overhang portion of the plurality of dies.

Each module may further include respective plurality of vertical conductive wires (e.g., first vertical conductive wire 1316, second vertical conductive wire 1326, third vertical conductive wire 1336 and fourth vertical conductive wire 1346) for connecting respective overhang portions of the plurality of dies to the respective bottom dielectric layers 1311, 1321, 1331, 1341 underneath the respective plurality of dies. The lowest die 1313a, 1323a, 1333a, 1343a of each module may be connected to the respective bottom dielectric layer 1311, 1321, 1331, 1341, for example, through respective conductive pads and/or lines between the lowest die 1313a, 1323a, 1333a, 1343a and the bottom dielectric layer 1311, 1321, 1331, 1341.

Each module may include a plurality of TIVs (e.g., first TIVs 1317, second TIVs 1327, third TIVs 1337) connecting its respective top dielectric layer (if any) and bottom dielectric layer. The top and bottom dielectric layers of each module may further include top and bottom bumps protruding away (e.g., upward and downward) from the top and bottom dielectric layers, respectively, configured to form vertical connections between two modules together with the vertical conductive wires and/or TIVs when the modules are stacked vertically on one another.

According to various aspects described herein, the modules 1302, 1304, 1306, 1308 are also different in sizes. In particular, the module size of the top module 1308 is the smallest and gradually increases towards the base module 1302. Besides the terraced structure of the dies within each module, the modules themselves are also laterally offset from each other to form a terraced structure such that the plurality of vertical conductive wires connecting the respective overhang portions of the plurality of dies from a higher module (e.g., middle and top modules such as second, third and fourth modules 1304, 1306, 1308) align with TIVs of a lower module(s) (e.g., a base module such as first module 1302) thus the I/Os of each die can be connected straight down to the bottom dielectric layer (or a bottom RDL) of the base module 1302.

The vertical connection paths of the pluralities of first, second, third and fourth dies are illustrated by arrows 1351, 1352, 1353, 1354, respectively. For purposes of avoiding clutter in the drawings, only the vertical connection path of the overhang portion of the highest die among the plurality of dies within each module is shown and labelled in FIG. 13.

The contact and first vertical conductive wires between the plurality of first dies and the bottom dielectric layer 1311 form respective first routing paths (e.g., first routing path illustrated by arrow 1351), that connect the signal/powers of the plurality of first dies within the first module 1302 straight down to the bottom dielectric layer 1331. The contacts and second vertical conductive wires connecting the plurality of second dies and the bottom bumps of the second bottom dielectric layer 1321 of the second module 1304, and the top bumps of the first top dielectric layer 1314 and the first TIVs of the first module 1302 form respective second routing paths (e.g., second routing path illustrated by arrow 1352), that connect the signal/power of each of the plurality of second dies within the second module 1304 straight down to the bottom dielectric layer 1311 of the first (base) module 1302.

Similarly, the contacts and third vertical conductive wires connecting the plurality of third dies and the bottom bumps of the third bottom dielectric layer 1331 of the third module 1306, the top bumps of the second top dielectric layer 1324 and the second TIVs and the bottom bumps of the second bottom dielectric layer 1321 of the second module 1304, and the top bumps of the first top dielectric layer 1314 and the first TIVs of the first module 1302 form respective third routing paths (e.g., third routing path illustrated by arrow 1353), that connect the signal/power of each of the plurality of third dies within the third module 606 straight down through the second module 1304 to the first bottom dielectric layer 1311 of the first (base) module 1302. The contacts and fourth vertical conductive wires connecting the plurality of fourth dies, the bottom bumps of the fourth bottom dielectric layer 1341 of the fourth module 1308, the top bumps of the third top dielectric layer 1334, the third TIVs, and the bottom bumps of the third bottom dielectric layer 1331 of the third module 1306, the top bumps of the second top dielectric layer 1324 and the second TIVs and the bottom bumps of the second bottom dielectric layer 1321 of the second module 1304, and the top bumps of the first top dielectric layer 1314 and the first TIVs of the first module 1302 form respective fourth routing paths (e.g., fourth routing path illustrated by arrow 1354), that connect the signal/power of each of the plurality of fourth dies within the fourth module 1308 down through the second and third modules 1304, 1306 to the bottom dielectric layer 1311 of the first (base) module 1302.

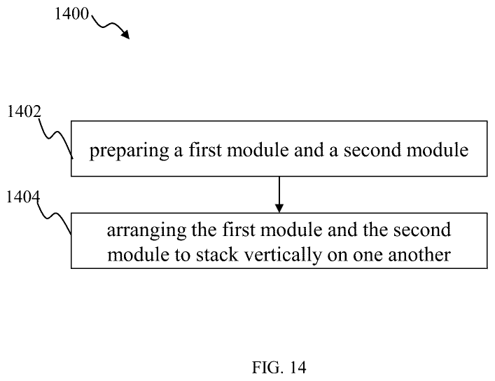

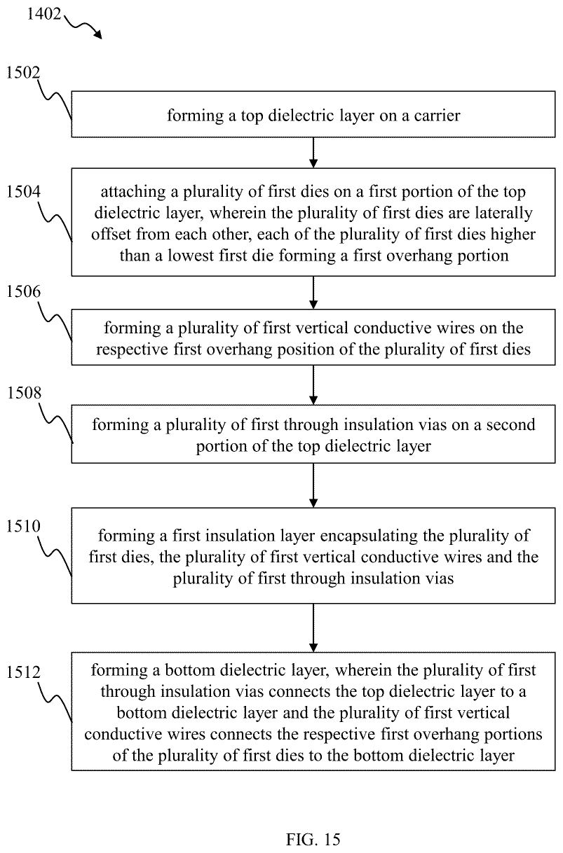

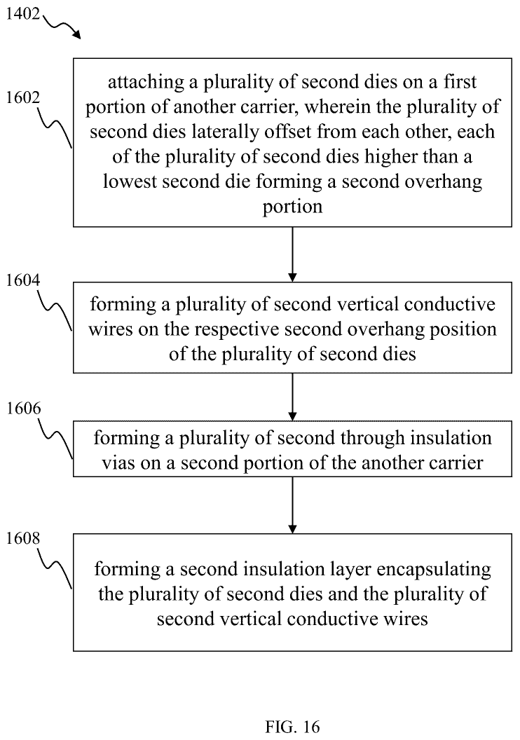

FIG. 14 shows a flow chart illustrating a method 1400 for fabricating a semiconductor device (e.g., semiconductor device 400, 500, 600, 800, 900, 1000, 1100, 1200, 1300) according to various aspects described herein. FIG. 15 shows a flow chart illustrating a part of processes of step 1402 of the method 1400 shown in FIG. 14. FIG. 16 shows a flow chart illustrating other part of processes of step 1402 of the method 1400 shown in FIG. 14.

According to various aspects described herein, the method 1400 may broadly include, in step 1402, preparing a first module and a second module; and in step 1404, arranging the first module and the second module to stack vertically on one another. The modules may be stacked through mass reflow (MR) or thermal compression bonding (TCB) bumping process so that the active dies can be stacked up to 16 dies and beyond across all stacked modules to meet high bandwidth and capacity requirements.

When preparing the first module in step 1402, the method may further include, in step 1502, forming a (first) top dielectric layer on a carrier; in step 1504, attaching a plurality of first dies on a first portion of the top dielectric layer, wherein the plurality of first dies laterally offset from each other, each of the plurality of first dies higher than a lowest first die forming a first overhang portion; in step 1506, forming a plurality of first vertical conductive wires on the respective first overhang portions of the plurality of first dies; in step 1508, forming a plurality of first TIVs on a second portion of the top dielectric layer; in step 1510, forming a first insulation layer (e.g., a molding layer) encapsulating the plurality of first dies, the plurality of first vertical conductive wires and the plurality of first TIVs, for example, by filling in mold resin or MUF in the entire module; in step 1512, forming the bottom dielectric layer, wherein the plurality of first TIVs connecting the top dielectric layer to a bottom dielectric layer, and the plurality of first vertical conductive wires connects the respective first overhang portions of the plurality of first dies to the bottom dielectric layer. In a non-limiting aspect, the forming the bottom dielectric layer in step 1512 may include forming a plurality of bottom bumps protruding away (e.g., downward) from the bottom dielectric layer, each of the plurality of bottom bumps connected to one of the plurality of first dies, one of the plurality of first vertical conductive wire or one of the plurality of first TIVs.

When preparing the second module in step 1402, the method may further include, in step 1602, attaching a plurality of second dies on a first portion of another carrier, where the plurality of second dies laterally offset from each other, each of the plurality of second dies higher than a lowest second die forming a second overhang portion; in step 1604, forming a plurality of second vertical conductive wires on the respective second overhang portions of the plurality of second dies; in step 1606, forming a plurality of second TIVs on a second portion of the another carrier; and in step 1608, forming a second insulation layer encapsulating the plurality of second dies and the plurality of second vertical conductive wires.

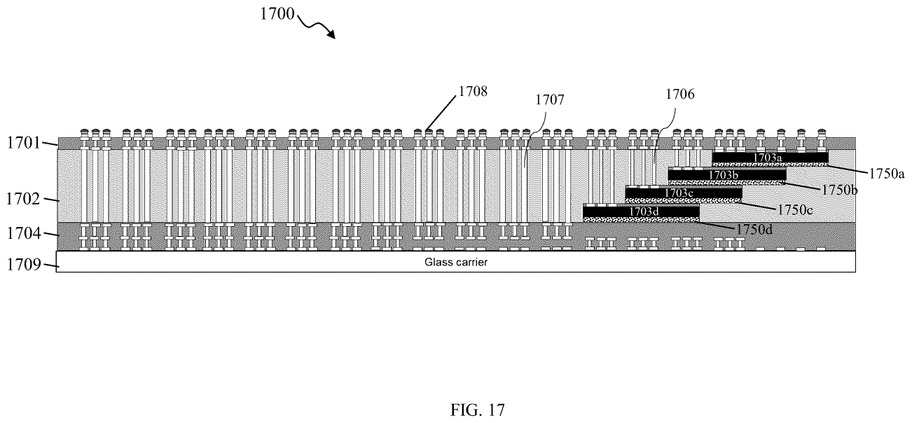

FIG. 17 shows a schematic diagram of a module 1700 fabricated through a method according to an aspect described herein before assembling into a semiconductor device. In an aspect, a first module (e.g., base module) of a semiconductor device (e.g., semiconductor device 400, 500, 600, 800, 900, 1000, 1100, 1200, 1300) may be separately prepared. In such case, the module 1700 may be a first module (e.g., base module), and preparing the first module 1700 in step 1502 may include forming a top dielectric layer 1704 (e.g., a top RDL) on a glass carrier 1709 in step 1502 followed by steps 1504, 1506, 1508, 1510, 1512 and 1514 to attach a plurality of first dies 1703 on a first portion of the top dielectric layer 1704, where the plurality of first dies are laterally offset from each other, each of the plurality of first dies (e.g., first dies 1703b, 1703c, 1703d) higher than a lowest first die (e.g., first die 1703a) forming a respective first overhang portion; form a plurality of first vertical conductive wires (e.g., first vertical conductive wire 1706) on the respective first overhang portions; form a plurality of first TIVs (e.g., first Cu TIV 1707) on a second portion of the top dielectric layer 1704; form a first insulation layer 1702 encapsulating the plurality of first dies 1703, the plurality of first vertical conductive wires and the plurality of first TIVs; and form a bottom dielectric layer 1701, wherein the plurality of first TIVs connecting the top dielectric layer 1704 to the bottom dielectric layer 1701, and the plurality of first vertical conductive wires connects the respective first overhang portions of the plurality of first dies to the bottom dielectric layer; and forming a plurality of bottom bumps (e.g., bottom bump 1708) protruding away (e.g., downward) from the bottom dielectric layer 1701, each of the plurality of bottom bumps connected to one of the plurality of first dies 1703, one of the plurality of first vertical conductive wire or one of the plurality of first TIVs. Subsequently, the glass carrier 1709 may be debonded from the top dielectric layer 1704 to form the base module 1700 to be assembled and arranged into a semiconductor device (e.g., semiconductor device 400, 500, 600, 800, 900, 1000, 1100, 1200, 1300).

In an aspect, in step 1504, to attach the plurality of first dies 1703 with N dies (N=4 in this example) on a first portion of the top dielectric layer 1704, a step of attaching a first die attach film (DAF) 1750d on the top dielectric layer 1704 is carried out. A first active die 1703d is then attached on the DAF 1750d. Subsequently, for each k, where 2≤k≤N, attaching a kth die attach film on the (k−1)th die, the kth die attach film to shift by a predetermined lateral displacement from the (k−1)th die; and attaching the kth active die on the kth die attach film such that the kth active die is shifted by the predetermined lateral displacement from the (k−1)th active die. In other words, subsequently to attaching the first active die 1750d, a second die attach film 1750c (k=2) is attached on the first active die 1750d, the second die attach film 1750c shifted from the first active die 1750d by a predetermined lateral displacement, and then the second active die 1703c is attached on the second die attach film 1750c such that the second active die 1703c is shifted from the first active die 1750d by the predetermined lateral displacement. Subsequently, a third die attach film 1750b (k=3) is attached on the second active die 1703c, the third die attach film 1750b shifted from the second active die 1703c by a predetermined lateral displacement and then the third active die 1703b is attached on the third die attach film 1750b such that the third active die 1703b is shifted from the second active die 1703c by the predetermined lateral displacement; and a fourth die attach film 1750a is attached on the third active die 1703b, the fourth die attach film 1750a shifted from the third active die 1703b by a predetermined lateral displacement and then the fourth active die 1703a is attached on the fourth die attach film 1750a such that the fourth active die 1703a is shifted from the third active die 1703b by the predetermined lateral displacement. Each of the active dies is shifted along a same lateral direction from each other, thus forming a terraced structure. It is appreciated that the active dies may be shifted by respective predetermined lateral displacement in different lateral directions, as illustrated in FIGS. 11 and 12 such that the plurality of active dies form a staggered structure instead.

Similarly, the second module and other modules such as the third and fourth modules (e.g., middle and top modules) of a semiconductor device (e.g., semiconductor device 400, 500, 600, 800, 900, 1000, 1100, 1200, 1300) and the respective pluralities of second and other dies stacked within each of the second and other modules may be separately prepared in a similar manner. In such case, in step 1404, the separately prepared second module is assembled and arranged to stack vertically on the first module, followed by arranging and assembling other modules (if any) to further stack vertically on the second module to fabricate a semiconductor device (e.g., semiconductor device 400, 500, 600, 800, 900, 1000, 1100, 1200, 1300). The modules may be stacked through MR or TCB bumping process so that the active dies can be stacked up to 16 dies and beyond across all stacked modules to meet high bandwidth and capacity requirements. Additionally, since the preparations of the modules are carried out separately, it is appreciated that the preparation of the first module, the second module and other modules may be carried out in any order.

In an alternative aspect, the module 1700 may be a second module, and the second module 1700 (e.g., top module) is first prepared on the glass carrier 1709 and the first module (e.g., base module) is then prepared on the second module 1700 to form a base module connecting the second module 1700. This may be referred to a sequential fanout RDP built-up module staking process. In such case, arranging the first module and the second module to stack vertically on one another in step 1404 includes performing the preparation of the second module first, for example, on the glass carrier 1709, and the preparation of the first module on the second module, e.g., the second insulation layer of the second module subsequent to the preparation of the second module. The preparing the first module 1700 in step 1502 may include forming a top dielectric layer (e.g., a top RDL) on the second module 1700 attached to the glass carrier or attached to another carrier (e.g., a third module), followed by steps 1504, 1506, 1508, 1510, 1512 and 1514 to attach a plurality of first dies 1703 on a first portion of the top dielectric layer, where the plurality of first dies are laterally offset from each other, each of the plurality of first dies higher than a lowest first die forming a respective first overhang portion; form a plurality of first vertical conductive wires on the respective first overhang portions; form a plurality of first TIVs on a second portion of the top dielectric layer; form a first insulation layer encapsulating the plurality of first dies, the plurality of first vertical conductive wires and the plurality of first TIVs; and form a bottom dielectric layer, wherein the plurality of first TIVs connecting the top dielectric layer to the bottom dielectric layer, and the plurality of first vertical conductive wires connects the respective first overhang portions of the plurality of first dies to the bottom dielectric layer; and forming a plurality of bottom bumps protruding away (e.g., downward) from the bottom dielectric layer, each of the plurality of bottom bumps connected to one of the plurality of first dies, one of the plurality of first vertical conductive wire or one of the plurality of first TIVs. Subsequently, after the preparation of the first module on the second module 1700, the glass carrier 1709 may be debonded from the top module (e.g., the second module) to form a semiconductor device (e.g., semiconductor device 400, 500, 600, 800, 900, 1000, 1100, 1200, 1300).

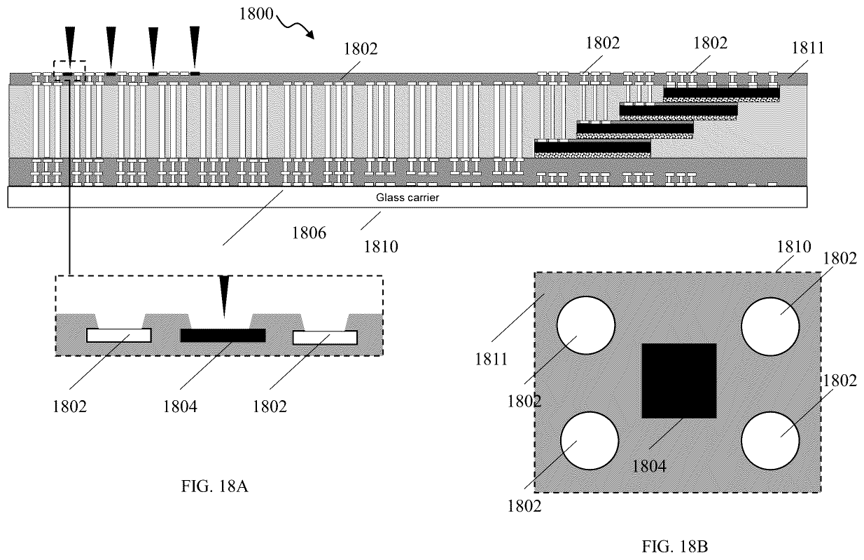

In a non-limiting aspect, a Known Good Unit Module (KGM) testing step may be carried out during the fabrication process. For example, it may be carried out before debonding the glass carrier. FIG. 18A shows a cross-sectional view of a second module when a KGM step is carried out when preparing a first module on the second module 1800 during a sequential fanout RDP build-up module stacking process. Inset 1810 of FIG. 18A shows an enlarged portion of the second module 1800. FIG. 18B shows a top view of the enlarged portion of the second module. According to the various aspects described herein, the step of forming the top dielectric layer 1811 of a first module (e.g., base module) on the second module 1800 (e.g., top module) fabricated on a glass carrier may include forming a routing layer having top conductive lines with first and second pads 1802 at respective ends for connecting the plurality of second vertical conductive wires, second dies and second TIVs on the second module 1800 to the plurality of first TIVs of the first module. Such step may further include forming sacrificial pads 1804 on the routing layer, each sacrificial pad connected to one or more pads among the first pads and second pads 1802, and performing a test (e.g., KGM test) using test probes (e.g., test probe 1806) to measure respective electrical properties of the second module, for example, to identify any defective die and connection. Each sacrificial pad 1804 may be formed near to and diagonally offset from one or more pads among the first pads and second pads 1802, as shown in FIG. 18B.

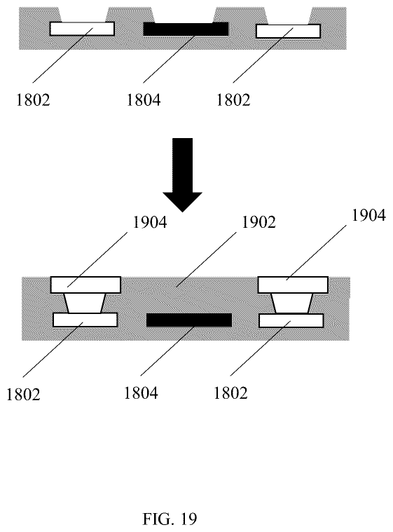

FIG. 19 shows a process of forming a top dielectric layer of a first module after performing a KGM test. Subsequent to the test, the formation of the top dielectric layer may continue, for example, by forming an additional top dielectric layer 1902 to cover the sacrificial pad 1804. Additional TIV pads 1904 may also be formed on pads 1802 for subsequent formations of the first TIVs of the first module.

In one example, the bottom dielectric layer 1701 with the plurality of bottom bumps 1708 of the second module 1700 may not be formed and the top dielectric layer of the first module is formed on the insulation layer 1702 of the second module 1700 in step 1502.

It is appreciated that the second module may be fabricated on a different carrier such as a third module which has been first prepared on the glass carrier, and the preparation of the first module is carried out once the preparation and the arranging of the second module on the third module is completed. State differently, a semiconductor device (e.g., semiconductor device 400, 500, 600, 800, 900, 1000, 1100, 1200, 1300) may be fabricated from top to base modules sequentially. Such process may be referred to as “one stop shop” process. Firstly, the top module may be formed on the glass carrier, one or more middle modules are formed and arranged vertically on the top module and a final base module is then arranged vertically on the middle modules. Subsequently, the glass carrier may be debonded from the top module to form a semiconductor device (e.g., semiconductor device 400, 500, 600, 800, 900, 1000, 1100, 1200, 1300).

Additionally, although a semiconductor device and a method of fabricating a semiconductor device having two to four modules stacked vertically on one another are described and illustrated, it is appreciated that the semiconductor device (e.g., semiconductor device 400, 500, 600, 800, 900, 1000, 1100, 1200, 1300) having than four modules may be achieved accordingly, for example, through module μ-bumps and top RDLs or through stacking on top RDLs shown in various aspects described herein.

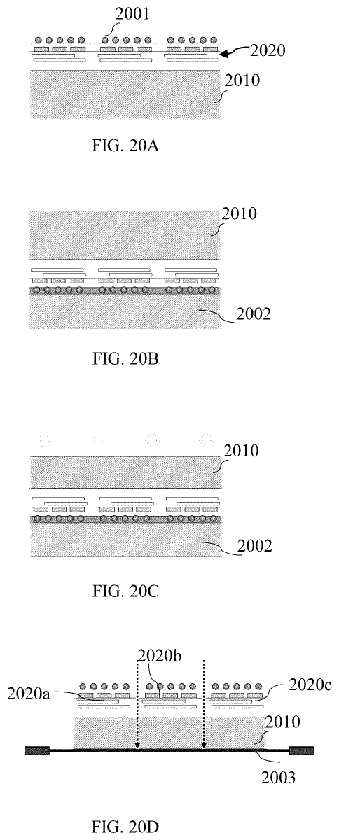

FIGS. 20A to 20D show schematic diagrams for fabricating a plurality of dies according to various aspects described herein.

FIG. 20A shows μ-bump formation process. The μ-bump formation process may include the creation of tiny solder bumps 2001 (e.g., bottom bumps, top bumps protruding away from a dielectric layer or RDL), also known as micro-bumps, for connecting dies (e.g. core dies, logic dies, memory dies) fabricated on a wafer 2010 (e.g. a DRAM wafer). The μ-bump formation process may involve several steps: starting with Physical Vapor Deposition (PVD) of Titanium (Ti) at 1,000 angstroms and PVD of Copper (Cu) at 3,000 angstroms to create a seed layer; followed by photolithography to define the bump locations; electroplating to build up the metal (e.g. Cu); stripping the photoresist; etching away the unnecessary seed layer; reflowing to form the bumps 2001; and descumming to clean the surface.

FIG. 20B shows carrier bond process. The carrier bond process may provide temporary support for wafers during various fabrication processes such as thinning, etching, and deposition. The carrier bond process may involve attaching the wafer 2010 to a carrier 2002, typically made of materials like glass or silicon, using a temporary adhesive such as thermal release tape or ultraviolet (UV)-curable adhesive. The carrier bond process may ensure mechanical stability and precise alignment, preventing damage to the thin, fragile wafers. The carrier bond process may include edge trimming to remove excess material from the edges of the wafer 2010 using mechanical or chemical methods, spin-coating that applies a uniform thin film of photoresist or other materials onto the wafer surface, and tungsten carbide (W2C) bonding process that involves depositing a thin layer of tungsten carbide onto the wafer or die surfaces and then applying pressure and heat to form a strong bond.

FIG. 20C shows backside grinding process. The backside grinding process may include two steps: background taping and backside grinding. The background taping may be the process of applying a protective adhesive tape to the front side of the wafer 2010, ensuring the delicate circuitry is shielded from mechanical stress and contamination during grinding. Following this, backside grinding may thin the wafer 2010 from the backside to the desired thickness through coarse and fine grinding stages. Coarse grinding may rapidly reduce the wafer's thickness using a diamond wheel, while fine grinding may achieve the precise final thickness and a smooth surface.

FIG. 20D shows de-bonding and die saw process. The de-bonding and die saw process may involve several steps to transform the fabricated dies 2020 into functional electronic components ready for integration into devices. Initially, the fabricated dies 2020 may undergo de-bonding to separate them from the carrier 2002. These individual dies 2020a, 2020b, 2020c may be then carefully mounted onto frames 2003 to provide structural support. Subsequent steps may include cleaning off residual adhesives to ensure pristine surfaces for further processing. Non-conductive film (NCF) lamination may follow, where layers are bonded using specialized techniques like laser grooving and vias (LGV) to facilitate electrical connections and mechanical support. Finally, die sawing may precisely cut the assembled components into individual dies 2020a, 2020b, 2020c, ensuring each is ready for packaging and integration into electronic products.

According to various aspects described herein, a process of fabricating a redistribution layer, e.g., dielectric layers 414, 411, 521, 611, 614, 624, 634, 821, 831, 841 of semiconductor devices 400, 500, 600, 800, 900, 1000, 1100, 1200, may begin with the application of polyimide coating, providing insulation and protection. Photolithography may then define intricate patterns on the polyimide layer using light-sensitive photoresist materials. After curing to stabilize the polyimide, titanium (Ti) (e.g. 1000 angstroms) and copper (Cu) (e.g. 3000 angstroms) may be sequentially deposited using PVD, forming adhesion layers and conductive traces, respectively. Additional photolithography steps may refine these layers, followed by electroplating to build up copper thickness and photoresist stripping to reveal the patterned traces. Etching of the seed layer may ensure precise alignment and connectivity for subsequent layers. This process may be repeated for each RDL.

According to various aspects described herein, a process of fabricating a dielectric layer may include a process of fabricating U-pads. The process may begin with applying a polyimide coating onto the substrate providing electrical insulation and physical protection. Photolithography may follow, where patterns are defined on the polyimide layer using light-sensitive photoresist materials, for guiding subsequent metallization steps. The polyimide may be then cured to stabilize its structure and optimize its properties for semiconductor applications. Next, titanium (Ti) and copper (Cu) may be sequentially deposited using PVD, with titanium serving as an adhesion layer and copper forming the conductive traces for interconnections. Additional photolithography steps may refine the copper layer, defining intricate circuit patterns. Electroplating may be employed to increase the thickness of the copper traces, ensuring they can efficiently conduct electrical currents. Subsequently, the photoresist layer may be stripped away, leaving behind the desired patterned copper traces. Etching of the seed layer may complete the process, ensuring precise alignment and connectivity for subsequent layers or components.

The following examples pertain to various aspects described herein.

Example 1 is a semiconductor device including: a first module including: a bottom dielectric layer; a first insulation layer on the bottom dielectric layer; a plurality of first dies stacked vertically within the first insulation layer, wherein the plurality of first dies are laterally offset from each other, each of the plurality of first dies higher than a lowest first die forming a respective first overhang portion; a top dielectric layer on the first insulation layer; and a plurality of first vertical conductive wires connecting the respective first overhang portions of the plurality of first dies to the bottom dielectric layer, wherein the first insulation layer includes a plurality of first TIVs connecting the top dielectric layer to the bottom dielectric layer; and a second module stacked vertically on the first module, the second module including: a second insulation layer; a plurality of second dies stacked vertically within the second insulation layer, wherein the plurality of second dies are laterally offset from each other, each of the plurality of second dies higher than a lowest second die forming a respective second overhang portion; and a plurality of second vertical conductive wires connecting the respective second overhang portions of the plurality of second dies to the top dielectric layer of the first module, wherein each of the plurality of first TIVs is coupled to one of the plurality of second dies, one of the plurality of second vertical conductive wires or a second TIV of the second module through the top dielectric layer.

In Example 2, the subject matter of Example 1 may optionally include the bottom dielectric layer further includes bottom conductive lines and a plurality of bottom bumps protruding downward from the bottom dielectric layer; each of the plurality of bottom bumps is coupled to one of the plurality of first dies, one of the plurality of first vertical conductive wires or one of the plurality of first TIVs through one of the bottom conductive lines.

In Example 3, the subject matter of Example 1 or 2 may optionally include that the top dielectric layer further includes a routing layer, the routing layer including top conductive lines; each of the plurality of first TIVs is coupled to the one of the plurality of second dies, the one of the plurality of second vertical conductive wires or the second TIV of the second module through one of the top conductive lines.

In Example 4, the subject matter of Example 3 may optionally include that the second module further includes a second bottom dielectric layer to which the second insulation layer is coupled, the second bottom dielectric layer including second bottom conductive lines and a plurality of second bottom bumps protruding downward from the second bottom dielectric layer, each of the plurality of second bottom bumps coupled to one of the second bottom conductive lines; and wherein one of the plurality of second dies, one of the plurality of second vertical conductive wires or the second TIV of the second module is coupled to the one of the respective top conductive lines of the routing layer through a second bottom conductive line of the second bottom conductive lines and a coupled second bottom bump of the plurality of second bottom bumps.

In Example 5, the subject matter of Example 3 or 4 may optionally include that the top conductive lines further includes first pads at respective first ends and second pads at respective second ends of the top conductive lines; the each of the plurality of first TIVs is coupled to one of the first pads and one of the plurality of second dies; one of the plurality of second vertical conductive wires or the second TIV of the second module is coupled to one of the second pads; and wherein the respective first pads have a first predetermined size, the respective second pads have a second predetermined size, the respective top conductive lines have a predetermined space from one another and/or the respective conductive lines have a predetermined width.

In Example 6, the subject matter of any one of Examples 1-5 may optionally include that the plurality of first dies and the plurality of second dies are stacked vertically within the first insulation layer and the second insulation layer at respective center portions of the first module and the second module, and the first insulation layer includes the plurality of first TIVs at one or more peripheral portions next to or surrounding the center portion of the first module.

In Example 7, the subject matter of any one of Examples 1-6 may optionally include that the plurality of first dies or the plurality of second dies include 1^{st} to Nth active dies, and for each k, where 2≤k≤N, the kth active die stacked vertically on the (k−1)th die is shifted by a predetermined lateral displacement from the (k−1)th active die.

In Example 8, the subject matter of Example 7 may optionally include that both the kth active die and the (k+1)th active die are shifted from the (k−1)th active die and the kth active die in a same lateral direction, respectively.

In Example 9, the subject matter of Example 7 may optionally include that the kth active die and the (k+1)th active die are shifted from the (k−1)th active die and the kth active die in opposite lateral directions.

In Example 10, the subject matter of Example 1 may optionally include that the top dielectric layer includes a plurality of first bumps protruding downward from the top dielectric layer, each of the plurality of first bumps coupled to one of the plurality of first TIVs; and the second module includes a second bottom dielectric layer, the second bottom dielectric layer including a plurality of second bottom bumps protruding downward from the second bottom dielectric layer and coupled to the plurality of first bumps; and wherein the each of the plurality of first TIVs is coupled to one of the plurality of second dies, one of the plurality of second vertical conductive wires or the second TIV of the second module through a first bump of the plurality of first bumps and a coupled second bottom bump of the plurality of second bottom bumps.

In Example 11, the subject matter of any one of Examples 1-10 may optionally include that the second module further comprises a second top dielectric layer on the second insulation layer; the second insulation layer comprises a plurality of second TIVs connecting the second top dielectric layer to first module; and the semiconductor device further comprises: a third module stacked vertically on the second module, the third module comprising: a third insulation layer; a plurality of third dies stacked vertically within the third insulation layer, wherein the plurality of third dies are laterally offset from each other, each of the plurality of third dies higher than a lowest third die forming a respective third overhang portion; and a plurality of third vertical conductive wires connecting the respective third overhang portions of the plurality of third dies to the second top dielectric layer of the second module, wherein each of the plurality of second TIVs is coupled to one of the plurality of third dies, one of the plurality of third vertical conductive wires or a third TIV of the third module through the second top dielectric layer.

In Example 12, the subject matter of Example 11 may optionally include that the second insulation layer, the plurality of second dies, and the plurality of second TIVs of the second module are identical to the first insulation layer, the plurality of first dies, and the plurality of first TIVs of the first module, respectively.

In Example 13, the subject matter of any one of Examples 1-12 may optionally include that a height of the first module spanning vertically from the bottom dielectric layer to the top dielectric layer is equal to or less than 200 μm.

Example 14 is a method of fabricating a semiconductor device, including: preparing a first module and a second module, the preparing the first module comprising: forming a top dielectric layer on a carrier; attaching a plurality of first dies on a first portion of the top dielectric layer, wherein the plurality of first dies laterally offset from each other, each of the plurality of first dies higher than a lowest first die forming a respective first overhang portion; forming a plurality of first vertical conductive wires on the respective first portions of the plurality of first dies; forming a plurality of first TIVs on a second portion of the top dielectric layer; forming a first insulation layer encapsulating the plurality of first dies, the plurality of first vertical conductive wires and the plurality of first TIVs; and forming a bottom dielectric layer, wherein the plurality of first TIVs connects the top dielectric layer to the bottom dielectric layer, and the plurality of first vertical conductive wires connects the respective first overhang portions of the plurality of first dies to the bottom dielectric layer; and the preparing of the second module comprising: attaching a plurality of second dies on a first portion of another carrier, wherein the plurality of second dies laterally offset from each other, each of the plurality of second dies higher than a lowest second die forming a respective second overhang portion; forming a plurality of second vertical conductive wires on the respective second overhang portions of the plurality of second dies; forming a plurality of second TIVs on a second portion of the another carrier; forming a second insulation layer encapsulating the plurality of second dies and the plurality of second vertical conductive wires; and arranging the first module and the second module to stack vertically on one another, wherein each of the plurality of first TIVs is coupled to one of the plurality of second dies, one of the plurality of second vertical conductive wires or a second TIV of the second module through the top dielectric layer.

In Example 15, the subject matter of Example 14 may optionally include that the carrier is the second insulation layer of the second module; and the arranging the first module and the second module to stack vertically on one another comprises performing the preparation of the first module on the second insulation layer subsequent to the preparation of the second module.

In Example 16, the subject matter of Example 14 may optionally include that the carrier is a glass carrier; the forming the bottom dielectric layer comprises forming a plurality of bottom bumps protruding downward from the bottom dielectric layer, each of the plurality of bottom bumps coupled to one of the plurality of first dies, one of the plurality of first vertical conductive wires or one of the plurality of first TIVs; the preparing the first module further comprises debonding the glass carrier subsequent to forming the plurality of bottom bumps; the preparing the second module further comprises forming a second bottom dielectric layer comprising second bottom conductive lines and forming a plurality of second bottom bumps protruding downward from the second bottom dielectric layer, each of the plurality of second bottom bumps coupled to one of the second bottom conductive lines; the arranging the first module and the second module to stack vertically on one another comprises arranging the second module to stack vertically on the first module; and the one of the plurality of second dies, the one of the plurality of second vertical conductive wires or the second TIV of the second module is coupled to the top dielectric layer through a second bottom conductive line of the second bottom conductive lines and a coupled second bottom bumps of the plurality of second bottom bumps.

In Example 17, the subject matter of Example 16 may optionally include that the preparing the first module further comprises forming a plurality of top bumps protruding away from the top dielectric layer, each of the plurality of top bumps connecting one of the plurality of first TIVs to one of the plurality of second bottom bump; and wherein the each of the plurality of first TIVs is coupled to one of the plurality of second dies, one of the plurality of second vertical conductive wires or the second TIV of the second module through a top bump of the plurality of top bumps and a coupled second bottom bump of the plurality of second bottom bumps.

In Example 18, the subject matter of any one of Examples 14-17 may optionally include that the forming the bottom dielectric layer further comprises forming bottom conductive lines each coupled to one of the plurality of bottom bumps; the each of the plurality of bottom bumps is coupled to one of the plurality of first dies, one of the plurality of first vertical conductive wires or one of the plurality of first TIVs through a coupled bottom conductive line of the bottom conductive lines; and the forming the top dielectric layer on the carrier comprises forming a routing layer comprising top conductive lines; and the each of the plurality of first TIVs at the second portion of the first module is coupled to one of the plurality of second dies, one of the plurality of second vertical conductive wires or the second TIV of the second module at the first portion of the second module through one of the top conductive lines.

In Example 19, the subject matter of Example 18 may optionally include that the forming the top dielectric layer on the carrier further comprises forming first pads at respective first ends and second pads at respective second ends of the top conductive lines; the each of the plurality of first TIVs is coupled to one of the first pads and one of the plurality of second dies, one of the plurality of second vertical conductive wires or the second TIV of the second module is coupled to one of the second pads; and wherein the respective first pads have a first predetermined size, the respective second pads have a second predetermined size, the respective top conductive lines have a predetermined space from one another and/or the respective conductive lines have a predetermined width.

In Example 20, the subject matter of Example 19 may optionally include that the forming the first pads at the respective first ends and second pads at the respective second ends comprises forming sacrificial pads on the routing layer each coupled to one or more pads among the first pads and second pads; and performing a test on the sacrificial pads to measure respective electrical properties of the second module.

In Example 21, the subject matter of any one of claims 14-20 may optionally include that the attaching the plurality of first dies within the first insulation layer and the attaching the plurality of second dies within the second insulation layer comprise attaching the plurality of first dies and the plurality of second dies within the second insulation layer at respective center portions of the first and second module; and forming the plurality of first TIVs comprises forming the plurality of first TIVs at one or more peripheral portions next to or surrounding the center portion of the first module.

In Example 22, the subject matter of any one of Examples 14-21 may optionally include that the plurality of first dies comprises first to Nth active dies; and the attaching the plurality of first dies on the first portion of the top dielectric layer comprises: attaching a first die attach film on the top dielectric layer; and attaching the first active die on the die attach film; for each k, where 2≤k≤N: attaching a kth die attach film on the (k−1)th die, the kth die attach film to shift by a predetermined lateral displacement from the (k−1)th die; and attaching the kth active die on the kth die attach film such that the kth active die is shifted by the predetermined lateral displacement from the (k−1)th active die.

In Example 23, the subject matter of Example 22 may optionally include arranging the kth die attach film and the (k+1)th die attach on which the kth active die and the (k+1)th active die attached to shift from the (k−1)th active die and the kth active die in a same lateral direction, respectively.

In Example 24, the subject matter of Example 22 may optionally include arranging the kth die attach film and the (k+1)th die attach on which the kth active die and the (k+1)th active die attached to shift from the (k−1)th active die and the kth active die in in opposite lateral directions.

In Example 25, the subject matter of any one of Examples 14-24 may optionally include that the another carrier is a second top dielectric layer; the second insulation layer comprises a plurality of second TIVs connecting the second top dielectric layer to first module, the method further comprising: preparing a third module comprising: attaching a plurality of third dies on a first portion of yet another carrier, wherein the plurality of third dies laterally offset from each other, each of the plurality of third dies higher than a lowest third die forming a respective third overhang portion; forming a plurality of third vertical conductive wires on the respective third overhang portions of the plurality of third dies; forming a plurality of third TIVs on a second portion of the yet another carrier; and forming a third insulation layer encapsulating the plurality of third dies, the plurality of third vertical conductive wires and the plurality of third TIVs; and arranging the second module and the third module to stack vertically on one another, wherein each of the plurality of second TIVs is coupled to one of the plurality of third dies, one of the plurality of third vertical conductive wires or a third TIV of the third module through the second top dielectric layer.

In Example 26, the subject matter of Example 25 may optionally include that second insulation layer, the plurality of second dies, and the plurality of second TIVs of the second module are identical to the first insulation layer, the plurality of first dies, and the plurality of first TIVs of the first module, respectively.

While this specification contains many details, these should not be understood as limitations on the scope of what may be claimed, but rather as descriptions of features specific to particular examples. Certain features that are described in this specification or shown in the drawings in the context of separate aspects can also be combined. Conversely, various features that are described or shown in the context of a single aspect can also be implemented in multiple aspects separately or in any suitable sub-combination.

Similarly, while steps/operations of the methods as described above are depicted in a particular order (e.g. as shown in the drawings), this should not be understood as requiring that such operations/steps be performed in the particular order shown or in sequential order, or that all illustrated operations be performed, to achieve desirable results. In certain circumstances, multitasking and parallel processing may be advantageous. For example, some operations/steps may occur in different orders and/or concurrently with other operations/steps apart from those illustrated and/or described herein. In addition, not all illustrated operations/steps may be required to implement one or more aspects or aspects described herein. Also, one or more of the steps depicted herein may be carried out in one or more separate acts and/or phases.

Moreover, the separation/integration of various system components in the aspects described above should not be understood as requiring such separation/integration in all aspects, and it should be understood that the described program components and systems can generally be integrated together in a single product or separated into multiple products.

A number of aspects have been described. Nevertheless, it will be understood that various modifications can be made. Accordingly, other aspects are within the scope of the following claims.

1. A semiconductor device, comprising:
a first module comprising:
a bottom dielectric layer;
a first insulation layer on the bottom dielectric layer;
a plurality of first dies stacked vertically within the first insulation layer, wherein the plurality of first dies are laterally offset from each other, each of the plurality of first dies higher than a lowest first die forming a respective first overhang portion;
a top dielectric layer on the first insulation layer; and
a plurality of first vertical conductive wires connecting the respective first overhang portions of the plurality of first dies to the bottom dielectric layer,
wherein the first insulation layer comprises a plurality of first through-insulation vias (TIVs) connecting the top dielectric layer to the bottom dielectric layer; and
a second module stacked vertically on the first module, the second module comprising:
a second insulation layer;
a plurality of second dies stacked vertically within the second insulation layer, wherein the plurality of second dies are laterally offset from each other, each of the plurality of second dies higher than a lowest second die forming a respective second overhang portion; and
a plurality of second vertical conductive wires connecting the respective second overhang portions of the plurality of second dies to the top dielectric layer of the first module,
wherein each of the plurality of first TIVs is coupled to one of the plurality of second dies, one of the plurality of second vertical conductive wires or a second TIV of the second module through the top dielectric layer.

2. The semiconductor device of claim 1, wherein the bottom dielectric layer further comprises bottom conductive lines and a plurality of bottom bumps protruding downward from the bottom dielectric layer; each of the plurality of bottom bumps is coupled to one of the plurality of first dies, one of the plurality of first vertical conductive wires or one of the plurality of first TIVs through one of the bottom conductive lines.

3. The semiconductor device of claim 1, wherein the top dielectric layer further comprises a routing layer, the routing layer comprising top conductive lines; and the each of the plurality of first TIVs is coupled to the one of the plurality of second dies, the one of the plurality of second vertical conductive wires or the second TIV of the second module through one of the top conductive lines.

4. The semiconductor device of claim 3, wherein the second module further comprises a second bottom dielectric layer to which the second insulation layer is coupled, the second bottom dielectric layer comprising second bottom conductive lines and a plurality of second bottom bumps protruding downward from the second bottom dielectric layer, each of the plurality of second bottom bumps coupled to one of the second bottom conductive lines; and wherein one of the plurality of second dies, one of the plurality of second vertical conductive wires or the second TIV of the second module is coupled to the one of the respective top conductive lines of the routing layer through a second bottom conductive line of the second bottom conductive lines and a coupled second bottom bump of the plurality of second bottom bumps.

5. The semiconductor device of claim 3, wherein the top conductive lines further comprises first pads at respective first ends and second pads at respective second ends of the top conductive lines; each of the plurality of first TIVs is coupled to one of the first pads and one of the plurality of second dies; one of the plurality of second vertical conductive wires or the second TIV of the second module is coupled to one of the second pads; and wherein the respective first pads and the respective second pads have a predetermined size, the respective first pads and second pads have a first predetermined space from one another, the respective top conductive lines have a second predetermined space from one another and/or the respective conductive lines have a predetermined width.

6. The semiconductor device of claim 1, wherein the plurality of first dies and the plurality of second dies are stacked vertically within the first insulation layer and the second insulation layer at respective center portions of the first module and the second module, and the first insulation layer comprises the plurality of first TIVs at one or more peripheral portions next to or surrounding the center portion of the first module.

7. The semiconductor device of claim 1, wherein the plurality of first dies or the plurality of second dies comprise 1^{st} to Nth active dies, and for each k, where 2≤k≤N, the kth active die stacked vertically on the (k−1)th die is shifted by a predetermined lateral displacement from the (k−1)th active die.

8. The semiconductor device of claim 7, wherein the kth active die and the (k+1)th active die are shifted from the (k−1)th active die and the kth active die in one of (i) a same lateral direction and (ii) opposite lateral directions.

9. The semiconductor device of claim 1, wherein the top dielectric layer comprises a plurality of first bumps protruding downward from the top dielectric layer, each of the plurality of first bumps coupled to one of the plurality of first TIVs; and the second module comprises a second bottom dielectric layer, the second bottom dielectric layer comprising a plurality of second bottom bumps protruding downward from the second bottom dielectric layer and coupled to the plurality of first bumps; and wherein each of the plurality of first TIVs is coupled to one of the plurality of second dies, one of the plurality of second vertical conductive wires or the second TIV of the second module through a first bump of the plurality of first bumps and a coupled second bottom bump of the plurality of second bottom bumps.

10. The semiconductor device of claim 1, wherein the second module further comprises a second top dielectric layer on the second insulation layer; the second insulation layer comprises a plurality of second TIVs connecting the second top dielectric layer to first module; and the semiconductor device further comprises:
a third module stacked vertically on the second module, the third module comprising:
a third insulation layer;
a plurality of third dies stacked vertically within the third insulation layer, wherein the plurality of third dies are laterally offset from each other, each of the plurality of third dies higher than a lowest third die forming a respective third overhang portion; and
a plurality of third vertical conductive wires connecting the respective third overhang portions of the plurality of third dies to the second top dielectric layer of the second module,
wherein each of the plurality of second TIVs is coupled to one of the plurality of third dies, one of the plurality of third vertical conductive wires or a third TIV of the third module through the second top dielectric layer.

11. A method of fabricating a semiconductor device, comprising:
preparing a first module and a second module, the preparing the first module comprising:
forming a top dielectric layer on a carrier;
attaching a plurality of first dies on a first portion of the top dielectric layer, wherein the plurality of first dies laterally offset from each other, each of the plurality of first dies higher than a lowest first die forming a respective first overhang portion;
forming a plurality of first vertical conductive wires on the respective first overhang portions of the plurality of first dies;
forming a plurality of first TIVs on a second portion of the top dielectric layer;
forming a first insulation layer encapsulating the plurality of first dies, the plurality of first vertical conductive wires and the plurality of first TIVs; and
forming a bottom dielectric layer, wherein the plurality of first TIVs connects the top dielectric layer to the bottom dielectric layer, and the plurality of first vertical conductive wires connects the respective first overhang portions of the plurality of first dies to the bottom dielectric layer; and
the preparing of the second module comprising:
attaching a plurality of second dies on a first portion of another carrier, wherein the plurality of second dies laterally offset from each other, each of the plurality of second dies higher than a lowest second die forming a respective second overhang portion;
forming a plurality of second vertical conductive wires on the respective second overhang portions of the plurality of second dies;
forming a plurality of second TIVs on a second portion of the another carrier;
forming a second insulation layer encapsulating the plurality of second dies and the plurality of second vertical conductive wires; and
arranging the first module and the second module to stack vertically on one another, wherein each of the plurality of first TIVs is coupled to one of the plurality of second dies, one of the plurality of second vertical conductive wires or a second TIV of the second module through the top dielectric layer.

12. The method of claim 11, wherein the carrier is the second module; and the arranging the first module and the second module to stack vertically on one another comprises performing the preparation of the first module on the second insulation layer subsequent to the preparation of the second module.

13. The method of claim 11, wherein the carrier is a glass carrier; the forming the bottom dielectric layer comprises forming a plurality of bottom bumps protruding downward from the bottom dielectric layer, each of the plurality of bottom bumps coupled to one of the plurality of first dies, one of the plurality of first vertical conductive wires or one of the plurality of first TIVs; the preparing the first module further comprises debonding the glass carrier subsequent to forming the plurality of bottom bumps; the preparing the second module further comprises forming a second bottom dielectric layer comprising second bottom conductive lines and forming a plurality of second bottom bumps protruding downward from the second bottom dielectric layer, each of the plurality of second bottom bumps coupled to one of the second bottom conductive lines; the arranging the first module and the second module to stack vertically on one another comprises arranging the second module to stack vertically on the first module; and the one of the plurality of second dies, the one of the plurality of second vertical conductive wires or the second TIV of the second module is coupled to the top dielectric layer through a second bottom conductive line of the second bottom conductive lines and a coupled second bottom bumps of the plurality of second bottom bumps.

14. The method of claim 13, wherein the preparing the first module further comprises forming a plurality of top bumps protruding upward from the top dielectric layer, each of the plurality of top bumps connecting one of the plurality of first TIVs to one of the plurality of second bottom bumps; and wherein each of the plurality of first TIVs is coupled to one of the plurality of second dies, one of the plurality of second vertical conductive wires or the second TIV of the second module through a top bump of the plurality of top bumps and a coupled second bottom bump of the plurality of second bottom bumps.

15. The method of claim 13, wherein the forming the bottom dielectric layer further comprises forming bottom conductive lines each coupled to one of the plurality of bottom bumps; each of the plurality of bottom bumps is coupled to one of the plurality of first dies, one of the plurality of first vertical conductive wires or one of the plurality of first TIVs through a coupled bottom conductive line of the bottom conductive lines; and the forming the top dielectric layer on the carrier comprises forming a routing layer comprising top conductive lines; and each of the plurality of first TIVs at the second portion of the first module is coupled to one of the plurality of second dies, one of the plurality of second vertical conductive wires or the second TIV of the second module at the first portion of the second module through one of the top conductive lines.

16. The method of claim 15, wherein the forming the top dielectric layer on the carrier further comprises forming first pads at respective first ends and second pads at respective second ends of the top conductive lines; each of the plurality of first TIVs is coupled to one of the first pads and one of the plurality of second dies, one of the plurality of second vertical conductive wires or the second TIV of the second module is coupled to one of the second pads; and wherein the respective first pads and the respective second pads have a predetermined size, the respective first pads and second pads have a first predetermined space from one another, the respective top conductive lines have a second predetermined space from one another and/or the respective conductive lines have a predetermined width.

17. The method of claim 16, wherein the forming the first pads at the respective first ends and second pads at the respective second ends comprises forming sacrificial pads on the routing layer each coupled to one or more pads among the first pads and second pads; and performing a test on the sacrificial pads to measure an electrical property of the second module.

18. The method of claim 11, wherein the attaching the plurality of first dies within the first insulation layer and the attaching the plurality of second dies within the second insulation layer comprise attaching the plurality of first dies and the plurality of second dies within the second insulation layer at respective center portions of the first and second module; and forming the plurality of first TIVs comprises forming the plurality of first TIVs at one or more peripheral portions next to or surrounding the center portion of the first module.

19. The method of claim 11, wherein the plurality of first dies comprises first to Nth active dies; and the attaching the plurality of first dies on the first portion of the top dielectric layer comprises:
attaching a first die attach film on the top dielectric layer;
attaching the first active die on the die attach film;
for each k, where 2≤k≤N:
attaching a kth die attach film on the (k−1)th die, the kth die attach film to shift by a predetermined lateral displacement from the (k−1)th die; and
attaching the kth active die on the kth die attach film such that the kth active die is shifted by the predetermined lateral displacement from the (k−1)th active die; and
the method further comprises one of:
(i) arranging the kth die attach film and the (k+1)th die attach on which the kth active die and the (k+1)th active die coupled to shift from the (k−1)th active die and the kth active die in a same lateral direction, respectively; and
(ii) arranging the kth die attach film and the (k+1)th die attach on which the kth active die and the (k+1)th active die coupled to shift from the (k−1)th active die and the kth active die in in opposite lateral directions.

20. The method of claim 11, wherein the another carrier is a second top dielectric layer; the second insulation layer comprises a plurality of second TIVs connecting the second top dielectric layer to first module, the method further comprising:
preparing a third module comprising:
attaching a plurality of third dies on a first portion of yet another carrier, wherein the plurality of third dies laterally offset from each other, each of the plurality of third dies higher than a lowest third die forming a respective third overhang portion;
forming a plurality of third vertical conductive wires on the respective third overhang portions of the plurality of third dies;
forming a plurality of third TIVs on a second portion of the yet another carrier; and
forming a third insulation layer encapsulating the plurality of third dies, the plurality of third vertical conductive wires and the plurality of third TIVs; and
arranging the second module and the third module to stack vertically on one another, wherein each of the plurality of second TIVs is coupled to one of the plurality of third dies, one of the plurality of third vertical conductive wires or a third TIV of the third module through the second top dielectric layer.
